(19) United States
(12) Patent Application Publication
(10) Pub. No.: US 2024/0240317 A1
(43) Pub. Date: Jul. 18, 2024

(54) ELECTRON-ENHANCED ATOMIC LAYER DEPOSITION (EE-ALD) METHODS AND DEVICES PREPARED BY SAME

(71) Applicant: THE REGENTS OF THE UNIVERSITY OF COLORADO, A BODY CORPORATE, Denver, CO (US)

(72) Inventors: Steven George, Boulder, CO (US); Zachary Sobell, Boulder, CO (US)

(21) Appl. No.: 18/096,668

(22) Filed: Jan. 13, 2023

(51) Int. Cl. C23C 16/455; C23C 16/34; C23C 16/48; H01J 37/06; H01J 37/317; H01L 21/768

(52) U.S. Cl. CPC C23C 16/45542; C23C 16/34; C23C 16/45553; C23C 16/45555; C23C 16/487; H01J 37/06; H01J 37/3178; H01L 21/76841

(57) ABSTRACT

In one aspect, the present invention provides a method of promoting nucleation and/or growth of a conductive film on a solid substrate. In certain embodiments, the method comprises contacting at least a portion of the surface of the solid substrate with a volatile metal precursor in the presence of a background gas, wherein the volatile metal precursor is chemisorbed or physisorbed to at least a portion of the surface of the solid substrate to provide a metal precursor-adsorbed surface, and contacting at least a portion of the metal precursor-adsorbed substrate with an electron beam in the presence of the background gas. The present invention further provides nanodevices and/or microdevices comprising a conductive film prepared according to the methods described herein.

### BACKGROUND OF THE INVENTION

A barrier metal is a material used in integrated circuits to chemically isolate semiconductors from metal interconnects, while maintaining an electrical connection between them. Ideally, the thickness of a diffusion barrier metal should be minimized, so as to allow additional space for a metal conductor. Thicker metal conductors enable higher conductivity and typically have low resistor-capacitor (RC) time constants, which are important for fast processing speeds.

Accordingly, titanium nitride (TiN) is an important material for semiconductor fabrication, as this material can be used as a diffusion barrier to prevent diffusion of copper and/or other conducting metals into surrounding materials having a low dielectric constant (k) in backend interconnects and vias. Additionally, the low resistivity of TiN films further contribute to the conductivity of the conducting line and lowers the RC time constant. Thus, a TiN film that nucleates rapidly, thereby permitting formation of ultrathin continuous TiN, would provide an optimum diffusion barrier.

Thus, there is a need in the art for methods of preparing a TiN film that nucleates rapidly and devices prepared by same. The present disclosure addresses this need.

### BRIEF SUMMARY OF THE INVENTION

In one aspect, the present invention provides a method of promoting nucleation and/or growth of a conductive film on a solid substrate.

In certain embodiments, the method comprises contacting at least a portion of the surface of the solid substrate with a volatile metal precursor in the presence of a background gas, wherein the volatile metal precursor is chemisorbed or physisorbed to at least a portion of the surface of the solid substrate to provide a metal precursor-adsorbed substrate surface.

In certain embodiments, the method comprises contacting at least a portion of the metal precursor-adsorbed substrate surface with an electron beam in the presence of the background gas.

In another aspect, the present invention provides a microdevice or nanodevice comprising a conductive film prepared according to the methods described herein.

### BRIEF DESCRIPTION OF THE FIGURES

The drawings illustrate generally, by way of example, but not by way of limitation, various embodiments of the present application.

FIG. 1 illustrates the effect of the NH₃ reactive background gas on Ti EE-ALD. The electron beam interacts with the surface to desorb surface species by electron stimulated desorption. The electron beam also interacts with the background gas to form reactive species such as radicals. The TiN EE-ALD comprises: (A) adsorption of the TDMAT (TiR₄) precursor; (B) removal of —R ligands by: (1) ESD, (2) •NH₂ radicals, and (3) •H radicals; (C) passivation of Ti dangling bonds by •NH₂; (D) removal of •H by ESD (shown) or radical abstraction processes (not shown); and (E) activated TiN surface for precursor adsorption.

FIG. 2A shows non-limiting reactants for use in the electron-enhanced atomic layer deposition (EE-ALD) methods described herein. FIG. 2B illustrates the sequence of inputs for a non-limiting embodiment of the EE-ALD described herein.

FIGS. 3A-3B show the production of a titanium nitride (TiN) film on a silicon nitride (Si₃N₄) substrate by EE-ALD with NH₃ background gas, as monitored by ellipsometry. FIG. 3A provides a graph showing the thickness of TiN as a function of EE-ALD cycles performed. FIG. 3B shows a subset of the graph shown in FIG. 3A, demonstrating nucleation at about the seventh dose (i.e., seventh cycle). Conditions: alternate dose, two at 0.20 Torr, 20 second electron beam exposure, 29 mA, 100 eV.

FIG. 4 depicts in vacuo Auger Electron Spectroscopy (AES) showing AES signals for C, Ti, N and O for TiN EE-ALD films grown on Si₃N₄. Pulsing sequence in seconds was (2, 2, 20, 1). TiN EE-ALD film grown with no RBG used 27 EE-ALD cycles. TiN EE-ALD film grown with RBG utilized 50 EE-ALD cycles. C AES signal is much lower when NH₃ RBG was present at ˜1 mTorr.

FIGS. 5A-5B provide graphs showing the depth profile of TiN films on a Si₃N₄ substrate, prepared as described herein, by X-ray photoelectron spectroscopy (XPS), wherein the TiN film is uncapped (FIG. 5A) or capped in situ with Si₃N₄ (FIG. 5B).

FIGS. 6A-6B show thickness (FIG. 6A) and Ti/(Ti+Si) composition (FIG. 6B) of TiN films on a silicon native oxide substrate, prepared by EE-ALD, as determined by ellipsometry and AES respectively. TiN films were prepared with 0, 5, 10, 15, 20, 30, and 50 cycles of EE-ALD.

FIG. 7 shows film roughness as a function of number of EE-ALD cycles performed for TiN films on a silicon native oxide substrate using six separate TiN films (i.e., film as loaded, film after initial electron beam exposure, 5 EE-ALD cycles, 10 EE-ALD cycles, 15 EE-ALD cycles, and 20 EE-ALD cycles). Roughness is observed to increase linearly for films prepared with about 20 or less cycles of EE-ALD. Roughness of the as loaded sample is high, wherein the sample is cleaned with isopropyl alcohol, acetone, and deionized water, then dried with ultra-high purity N₂ gas. Post 5 minute electron beam exposure with ˜1 mTorr NH₃ RBG the sample roughness is lessened due to surface impurity removal by the interaction of the elctron beam and NH₃.

FIG. 8 depicts a grazing incidence x-ray diffraction (GIXRD) spectrum of TiN-EE ALD films grown on a silicon thermal oxide substrate after 200 EE-ALD cycles. Conditions: pulse sequence (1 s, 2 s, 20 s, 1 s), ˜1 mTorr background NH₃ pressure. Miller indices of diffraction peaks for crystalline TiN are shown for comparison.

FIG. 9A depicts resistivity and TiN EE-ALD film thickness on Si thermal oxide versus number of EE-ALD cycles measured using in situ ellipsometry. Pulsing sequence in seconds was (1, 2, 20, 1) with NH₃ background pressure of ˜1 mTorr. Growth per cycle was 0.75 Å/cycle. Resistivity reaches a value of ˜110 μΩ cm after >100 EE-ALD cycles at TiN EE-ALD film thickness of >60 Å. FIG. 9B depicts a subset of FIG. 9A showing 0 to 30 cycles.

FIG. 10 shows film roughness as a function of number of EE-ALD cycles performed for TiN films on a silicon native oxide substrate. Roughness is observed to increase slightly and then level out at an RMS roughness of ˜3.5 Å.

FIG. 11 provides a graph depicting expansion of steady state region shown in FIG. 2A showing TiN EE-ALD film thickness on Si₃N₄ versus number of EE-ALD cycles measured using in situ ellipsometry. Pulsing sequence in seconds was (2, 2, 20, 1) with NH₃ background pressure of −1 mTorr. Growth per cycle was 1.8/cycle.

FIG. 12 provides a comparison of the experimentally measured imaginary part of the pseudo dielectric function (ε₂) between TiN EE-ALD film on SiO₂ thermal oxide, as described herein, PE-ALD TiN film, as previously described in the literature, and results for TiN in J.A. Woollam CompleteEASE database. For TiN EE-ALD film on SiO₂ thermal oxide, pulsing sequence in seconds was (1, 2, 20, 1) with NH₃ background pressure of −1 mTorr.

### DETAILED DESCRIPTION OF THE INVENTION

Ultrathin metal diffusion barriers in backend interconnects are needed to provide as much space as possible for conducting lines in vias. To achieve such continuous ultrathin barriers, fabrication methods which provide rapid nucleation are required. Accordingly, in one aspect, the present disclosure relates to the discovery of a fabrication method utilizing electron-enhanced atomic layer deposition (EE-ALD) to achieve rapid nucleation of TiN barrier films.

EE-ALD uses sequential exposure of precursors and low energy electrons to deposit thin films on a substrate. The precursor molecular first adsorbs on the substrate (i.e., step (a)), then low energy electrons desorb the ligands from the precursor via electron-stimulated desorption (ESD) (i.e., step (b)). The process of ligand desorption leaves behind open sites for further precursor adsorption. Repeating the precursor and low energy electron sequential exposures produces the EE-ALD film growth.

The present disclosure further relates to EE-ALD methods utilizing a reactive background gas (e.g., NH₃) concurrently with EE-ALD. The use of a reactive background gas in EE-ALD is enabled by the use of a hollow cathode plasma electron source (HC-PES), as described in Sobell et al. (J. Vac. Sci. Technol. A 2021, 39:042403), as the HC-PES can operate with reactor pressures in the mTorr range. Previously described EE-ALD methods utilized an electron gun as the electron source which necessarily comprises a high temperature filament, thereby precluding the use of reactive background gases.

The EE-ALD methods described herein may be performed at lower temperatures (i.e., temperatures of less than about 100° C.) to produce films with lower resistivity than films prepared by alternative techniques. In certain embodiments, the presence of a reactive background gas can improve the purity of the EE-ALD film. In certain embodiments, the background gas can tune the composition of the EE-ALD film.

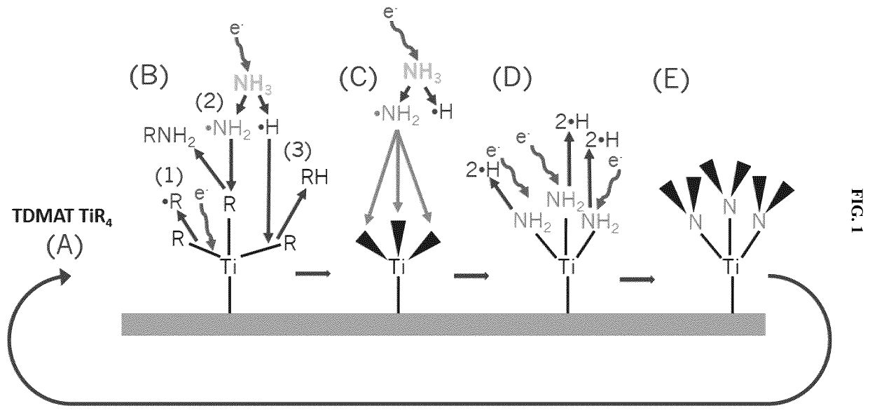

In one aspect, the present disclosure describes preparation of TiN films, using EE-ALD, from tetrakis(dimethylamido)titanium (TDMAT) as the titanium precursor and NH₃ as the background gas at a continuous pressure of about 1 mTorr. Films described herein have been fabricated on a number of substrate surfaces, including but not limited to silicon nitride (Si₃N₄), crystalline silicon (i.e., silicon wafer or Si), and thermal silicon oxide (i.e., SiO₂). Without wishing to be bound by theory, it has been proposed that exposure of NH₃ to the electron beam generates H and N radicals, wherein the N radicals facilitate Ti nitridation and the H radicals facilitate removal of carbon as CH₄. An illustration of the effect of the NH₃ reactive background gas on Ti EE-ALD is shown in FIG. 1.

Reference will now be made in detail to certain embodiments of the disclosed subject matter, examples of which are illustrated in part in the accompanying drawings. While the disclosed subject matter will be described in conjunction with the enumerated claims, it will be understood that the exemplified subject matter is not intended to limit the claims to the disclosed subject matter.

Throughout this document, values expressed in a range format should be interpreted in a flexible manner to include not only the numerical values explicitly recited as the limits of the range, but also to include all the individual numerical values or sub-ranges encompassed within that range as if each numerical value and sub-range is explicitly recited. For example, a range of “about 0.1% to about 5%” or “about 0.1% to 5%” should be interpreted to include not just about 0.1% to about 5%, but also the individual values (e.g., 1%, 2%, 3%, and 4%) and the sub-ranges (e.g., 0.1% to 0.5%, 1.1% to 2.2%, 3.3% to 4.4%) within the indicated range. The statement “about X to Y” has the same meaning as “about X to about Y,” unless indicated otherwise. Likewise, the statement “about X, Y, or about Z” has the same meaning as “about X, about Y, or about Z,” unless indicated otherwise.

In this document, the terms “a,” “an,” or “the” are used to include one or more than one unless the context clearly dictates otherwise. The term “or” is used to refer to a nonexclusive “or” unless otherwise indicated. The statement “at least one of A and B” or “at least one of A or B” has the same meaning as “A, B, or A and B.” In addition, it is to be understood that the phraseology or terminology employed herein, and not otherwise defined, is for the purpose of description only and not of limitation. Any use of section headings is intended to aid reading of the document and is not to be interpreted as limiting; information that is relevant to a section heading may occur within or outside of that particular section. All publications, patents, and patent documents referred to in this document are incorporated by reference herein in their entirety, as though individually incorporated by reference.

In the methods described herein, the acts can be carried out in any order, except when a temporal or operational sequence is explicitly recited. Furthermore, specified acts can be carried out concurrently unless explicit claim language recites that they be carried out separately. For example, a claimed act of doing X and a claimed act of doing Y can be conducted simultaneously within a single operation, and the resulting process will fall within the literal scope of the claimed process.

### Definitions

As used herein, unless defined otherwise, all technical and scientific terms generally have the same meaning as commonly understood by one of ordinary skill in the art to which this invention belongs. Generally, the nomenclature used herein and the laboratory procedures in surface chemistry are those well-known and commonly employed in the art.

The term “about” as used herein can allow for a degree of variability in a value or range, for example, within 10%, within 5%, or within 1% of a stated value or of a stated limit of a range, and includes the exact stated value or range.

As used herein, the term “ALD” refers to atomic layer deposition, which is a thin film deposition method. In certain embodiments, the term “thin” refers to a range of thickness from about 0.1 nm to about 300 nm. ALD uses a self-limiting reaction sequence that deposits films in discrete steps limited by surface site chemical reactions. It produces continuous films with atomically controlled thicknesses, high conformality, and typically pinhole-free and atomically smooth surfaces. These are essential properties as design constraints push device technologies to ever smaller sizes.

The term “chemisorb” as used herein refers to a type of adsorption which involves a chemical reaction between a substrate surface and an adsorbate (i.e., material adsorbed to the substrate surface). In certain embodiments, chemical bonds are formed between the adsorbate and the substrate surface.

The term “electron beam” as used herein refers to a stream of electrons in a gas or vacuum. Contact of a substrate with an electron beam necessarily comprises contact of the substrate with one or more electrons. The properties of the electron beam (e.g., energy, current, and duration, inter alia) of the electron beam may vary between electron sources and/or experimental conditions.

The terms “halo,” “halogen,” or “halide” group, as used herein, by themselves or as part of another substituent, mean, unless otherwise stated, a fluorine, chlorine, bromine, or iodine atom.

As used herein, the term “μm” is the abbreviation for “micron” or “micrometer”, and it is understood that 1 μm=0.001 mm=10⁻⁶ m=1 millionth of a meter.

As used herein, the term “nanodevice” refers to a device that has at least one component with at least one spatial dimension less than 1 micron.

As used herein, the term “nm” is the abbreviation for “nanometer” and it is understood that 1 nm=1 nanometer=10⁻⁹ m=1 billionth of a meter.

The term “nucleation” as used herein refers to initial formation of either a thermodynamic phase or structure (e.g., particle, crystal, and/or film) on the surface of a substrate which has been subjected to atomic layer deposition.

The term “organic group” as used herein refers to any carbon-containing functional group. Examples can include an oxygen-containing group such as an alkoxy group, aryloxy group, aralkyloxy group, oxo(carbonyl) group; a carboxyl group including a carboxylic acid, carboxylate, and a carboxylate ester; a sulfur-containing group such as an alkyl and aryl sulfide group; and other heteroatom-containing groups. Non-limiting examples of organic groups include OR, OOR, OC(O)N(R)₂, CN, CF₃, OCF₃, R, C(O), methylenedioxy, ethylenedioxy, N(R)₂, SR, SOR, SO₂R, SO₂N(R)₂, SO₃R, C(O)R, C(O)C(O)R, C(O)CH₂C(O)R, C(S)R, C(O)OR, OC(O)R, C(O)N(R)₂, OC(O)N(R)₂, C(S)N(R)₂, (CH₂)₀₋₂N(R)C(O)R, (CH₂)₀₋₂N(R)N(R)₂, N(R)N(R)C(O)R, N(R)N(R)C(O)OR, N(R)N(R)CON(R)₂, N(R)SO₂R, N(R)SO₂N(R)₂, N(R)C(O)OR, N(R)C(O)R, N(R)C(S)R, N(R)C(O)N(R)₂, N(R)C(S)N(R)₂, N(COR)COR, N(OR)R, C(═NH)N(R)₂, C(O)N(OR)R, C(═NOR)R, and substituted or unsubstituted (C₁-C₁₀₀)hydrocarbyl, wherein R can be hydrogen (in examples that include other carbon atoms) or a carbon-based moiety, and wherein the carbon-based moiety can be substituted or unsubstituted.

The term “physisorbed” as used herein refers to a type of adsorption which comprises a physical attraction between a substrate surface and an adsorbate (i.e., material adsorbed to the substrate surface). In certain embodiments, the physical attraction may comprise dispersion and/or van der Waals interactions between the adsorbate and the substrate surface.

The term “resistivity” as used herein refers to electrical resistivity, commonly represented by the Greek letter “p”, a fundamental property of a material that measures how strongly said material resists electrical current.

The term “room temperature” as used herein refers to a temperature of about 15° C. to 28° C.

The term “substantially” as used herein refers to a majority of, or mostly, as in at least about 50%, 60%, 70%, 80%, 90%, 95%, 96%, 97%, 98%, 99%, 99.5%, 99.9%, 99.99%, or at least about 99.999% or more, or 100%. The term “substantially free of” as used herein can mean having none or having a trivial amount of, such that the amount of material present does not affect the material properties of the composition including the material, such that the composition is about 0 wt % to about 5 wt % of the material, or about 0 wt % to about 1 wt %, or about 5 wt % or less, or less than, equal to, or greater than about 4.5 wt %, 4, 3.5, 3, 2.5, 2, 1.5, 1, 0.9, 0.8, 0.7, 0.6, 0.5, 0.4, 0.3, 0.2, 0.1, 0.01, or about 0.001 wt % or less. The term “substantially free of” can mean having a trivial amount of, such that a composition is about 0 wt % to about 5 wt % of the material, or about 0 wt % to about 1 wt %, or about 5 wt % or less, or less than, equal to, or greater than about 4.5 wt %, 4, 3.5, 3, 2.5, 2, 1.5, 1, 0.9, 0.8, 0.7, 0.6, 0.5, 0.4, 0.3, 0.2, 0.1, 0.01, or about 0.001 wt % or less, or about 0 wt %.

### Methods

### Electron-Enhanced Atomic Layer Deposition (EE-ALD)

In one aspect, the invention provides a method of promoting nucleation and/or growth of a conductive film on a solid substrate.

In certain embodiments, the method includes contacting at least a portion of the surface of the solid substrate with a volatile metal precursor in the presence of a background gas, wherein the volatile metal precursor is chemisorbed or physisorbed to at least a portion of the surface of the solid substrate to provide a metal precursor-adsorbed substrate surface (i.e., step (a)).

In certain embodiments, the method includes contacting at least a portion of the metal precursor-adsorbed substrate surface with an electron beam in the presence of the background gas (i.e., step (b)).

In certain embodiments, the volatile metal precursor comprises a metal. In certain embodiments, the volatile metal precursor includes a metal-halogen complex. In certain embodiments, the volatile metal precursor includes a metal-organic complex. In certain embodiments, the volatile metal precursor includes a mixture of any of a metal, metal-halogen, complex, and metal-organic complex.

In certain embodiments, the volatile metal precursor is an amide or imide of Be, Sc, Ti, V, Cr, Mn, Fe, Co, Ni, Cu, Zn, Al, Si, Ga, Ge, As, Se, Y, Zr, Nb, Mo, Sn, Sb, Te, La, Hf, Ta, W, Pb, or Bi. In certain embodiments, the volatile metal precursor is a halide of B, C, Al, Si, P, Ti, V, Cr, Mn, Cu, Zn, Ga, Ge, Zr, Hb, Mo, Cd, In, Sn, Sb, Hf, Ta, W, or Pb. In certain embodiments, the volatile metal precursor is an alkyl of B, Al, Si, Zn, Ga, Ge, Cd, In, Sn, Sb, Te, Hg, or Bi. In certain embodiments, the volatile metal precursor is an alkoxide of B, Al, Si, Ti, V, Ni, Ge, Zr, Nb, Hf, Ta, or Gd. In certain embodiments, the volatile metal precursor is a cyclopentadienyl of Mg, Ca, Sc, Ti, Mn, Ge, Co, Ni, Sr, Y, Zr, Ru, In, Ba, La, Hf, or Pt. In certain embodiments, the volatile metal precursor comprises a beta-diketonate or amidinate.

In certain embodiments, the metal is selected from the group consisting of Ti, Ta, W, Mo, Zr, Hf, Zn, Sc, Nb, Cu, Ni, Pt, Ru, Ni, and Al. In certain embodiments, the metal-halogen complex includes a metal selected from the group consisting of Ti, Ta, W, Mo, Zr, Hf, Zn, Sc, Nb, Cu, Ni, Pt, Ru, Ni, or Al. In certain embodiments, the metal-organic complex includes a metal selected from the group consisting of Ti, Ta, W, Mo, Zr, Hf, Zn, Sc, Nb, Cu, Ni, Pt, Ru, Ni, and Al.

In certain embodiments, the volatile metal precursor is tetrakis(dimethylamino)titanium (TDMAT).

In certain embodiments, the background gas has a pressure of about 1 mTorr to about 2 mTorr.

In certain embodiments, the background gas comprises at least one selected from the group consisting of a hydride gas, an oxide gas, a nitride gas, a sulfide gas, and a halide or halogen gas. In certain embodiments, the hydride gas is at least one selected from the group consisting of ammonia (NH₃), CH₄, H₂O, HF, HCl, SiH₄, PH₃, H₂S, GeH₄, AsH₃, and H₂Se. In certain embodiments, the oxide gas is at least one selected from the group consisting of O₂, O₃, H₂O₂, and H₂O. In certain embodiments, the nitride gas is at least one selected from the group consisting of N₂ and NH₃. In certain embodiments, the sulfide gas is at least one selected from the group consisting of S₈ and H₂S. In certain embodiments, the halide or halogen gas is at least one selected from the group consisting of F₂, HF, SF₆, NF₃, BF₃, Cl₂, HCl, BCl₃, HBr, Br₂, BBr₃, HI, and I₂.

In certain embodiments, the background gas is ammonia.

In certain embodiments, the background gas comprises a mixture of two or more distinct chemical species. In certain embodiments, the use of a background gas comprising a mixture of gases permits the deposition of ternary, quaternary, or more diverse alloy metals.

In certain embodiments, the solid substrate includes a semiconductor. In certain embodiments, the solid substrate includes a ceramic. In certain embodiments, the solid substrate includes a metal. In certain embodiments, the solid substrate includes a polymer. In certain embodiments, the solid substrate includes a metal-oxide. In certain embodiments, the solid substrate includes a mixture of any of a semiconductor, ceramic, metal, and metal-oxide.

In certain embodiments, the semiconductor includes silicon. In certain embodiments, the semiconductor is silicon nitride (Si₃N₄). In certain embodiments, the semiconductor is silicon dioxide (SiO₂). In certain embodiments, the semiconductor is crystalline silicon.

In certain embodiments, the contacting of the volatile metal precursor and the solid substrate occurs for a period of about 0.1 to 10 seconds. In certain embodiments, the contacting of the volatile metal precursor and the solid substrate occurs for a period of more than about 0.1 to 10 seconds. In certain embodiments, the contacting of the volatile metal precursor and the solid substrate occurs for a period of less than about 0.1 to 10 seconds.

In certain embodiments, the contacting of the volatile metal precursor and the solid substrate occurs for a period of about 0.1, 0.2, 0.3, 0.4, 0.5, 0.6, 0.7, 0.8, 0.9, 1, 1.1, 1.2, 1.3, 1.4, 1.5, 1.6, 1.7, 1.8, 1.9, 2, 2.1, 2.2, 2.3, 2.4, 2.5, 2.6, 2.7, 2.8, 2.9, 3, 3.1, 3.2, 3.3, 3.4, 3.5, 3.6, 3.7, 3.8, 3.9, or about 4.0 seconds.

In certain embodiments, the contacting of the metal precursor-adsorbed substrate surface and the electron beam occurs for a period of about 10, 11, 12, 13, 14, 15, 16, 17, 18, 19, 20, 21, 22, 23, 24, 25, 26, 27, 28, 29, 30, 31, 32, 33, 34, 35, 36, 37, 38, 39, or about 40 seconds. In certain embodiments, the contacting of the metal precursor-adsorbed substrate surface and the electron beam occurs for a period of less than about 10 seconds. In certain embodiments, the contacting of the metal precursor-adsorbed substrate surface and the electron beam occurs for a period of more than about 40 seconds.

In certain embodiments, the contacting of the metal precursor-adsorbed substrate surface and the electron beam occurs for a period of about 20 seconds.

In certain embodiments, the electron beam has a current selected from the group consisting of about 0.1, 0.2, 0.3, 0.4, 0.5, 0.6, 0.7, 0.8, 0.9, 1.0, 1, 2, 3, 4, 5, 6, 7, 8, 9, 10, 11, 12, 13, 14, 15, 16, 17, 18, 19, 20, 21, 22, 23, 24, 25, 26, 27, 28, 29, 30, 31, 32, 33, 34, 35, 36, 37, 38, 39, 40, 41, 42, 43, 44, 45, 46, 47, 48, 49, 50, 51, 52, 53, 54, 55, 56, 57, 58, 59, 60, 61, 62, 63, 64, 65, 66, 67, 68, 69, 70, 71, 72, 73, 74, 75, 76, 77, 78, 79, 80, 81, 82, 83, 84, 85, 86, 87, 88, 89, 90, 91, 92, 93, 94, 95, 96, 97, 98, 99, and about 100 mA. In certain embodiments, the electron beam has a current less than about 0.1 mA. In certain embodiments, the electron beam has a current which is greater than about 100 mA. In certain embodiments, the electron beam has an energy selected from the group consisting of about 1, 2, 3, 4, 5, 6, 7, 8, 9, 10, 11, 12, 13, 14, 15, 16, 17, 18, 19, 20, 21, 22, 23, 24, 25, 26, 27, 28, 29, 30, 31, 32, 33, 34, 35, 36, 37, 38, 39, 40, 41, 42, 43, 44, 45, 46, 47, 48, 49, 50, 51, 52, 53, 54, 55, 56, 57, 58, 59, 60, 61, 62, 63, 64, 65, 66, 67, 68, 69, 70, 71, 72, 73, 74, 75, 76, 77, 78, 79, 80, 81, 82, 83, 84, 85, 86, 87, 88, 89, 90, 91, 92, 93, 94, 95, 96, 97, 98, 99, 100, 101, 102, 103, 104, 105, 106, 107, 108, 109, 110, 111, 112, 113, 114, 115, 116, 117, 118, 119, 120, 121, 122, 123, 124, 125, 126, 127, 128, 129, 130, 131, 132, 133, 134, 135, 136, 137, 138, 139, 140, 141, 142, 143, 144, 145, 146, 147, 148, 149, and about 150 eV. In certain embodiments, the electron beam has an energy of less than about 1 eV. In certain embodiments, the electron beam has an energy which is greater than about 150 eV. In certain embodiments, the electron beam is generated using a hollow cathode plasma electron source (HC-PES).

In certain embodiments, steps (a) and (b) occur at a temperature selected from the group consisting of about 18, 19, 20, 21, 22, 23, 24, 25, 26, 27, 28, 29, 30, 31, 32, 33, 34, 35, 36, 37, 38, 39, 40, 41, 42, 43, 44, 45, 46, 47, 48, 49, 50, 51, 52, 53, 54, 55, 56, 57, 58, 59, 60, 61, 62, 63, 64, 65, 66, 67, 68, 69, 70, 71, 72, 73, 74, 75, 76, 77, 78, 79, 80, 81, 82, 83, 84, 85, 86, 87, 88, 89, 90, 91, 92, 93, 94, 95, 96, 97, 98, 99, 100, 101, 102, 103, 104, 105, 106, 107, 108, 109, 110, 111, 112, 113, 114, 115, 116, 117, 118, 119, 120, 121, 122, 123, 124, 125, 126, 127, 128, 129, 130, 131, 132, 133, 134, 135, 136, 137, 138, 139, 140, 141, 142, 143, 144, 145, 146, 147, 148, 149, and about 150° C.

In certain embodiments, steps (a) and (b) occur at a temperature of less than about 18° C. In certain embodiments, steps (a) and (b) occur at a temperature which is greater than about 150° C.

In certain embodiments, nucleation occurs by performing 5 cycles of steps (a)-(b). In certain embodiments, nucleation occurs by performing 6 cycles of steps (a)-(b). In certain embodiments, nucleation occurs by performing 7 cycles of steps (a)-(b). In certain embodiments, nucleation occurs by performing 8 cycles of steps (a)-(b). In certain embodiments, nucleation occurs by performing 9 cycles of steps (a)-(b). In certain embodiments, nucleation occurs by performing 10 cycles of steps (a)-(b).

In certain embodiments, steps (a)-(b) are repeated one or more times, wherein each cycle of steps (a)-(b) increases the thickness of the conductive film by an amount selected from the group consisting of about 0.5, 0.6, 0.7, 0.8, 0.9, 1.0, 1.1, 1.2, 1.3, 1.4, 1.5, 1.6, 1.7, 1.8, 1.9 and about 2.0 Å.

In certain embodiments, the conductive film comprises titanium nitride (TiN).

In certain embodiments, the TiN film comprises 91%, 92%, 93%, 94%, 95%, 96%, 97%, 98%, 99%, or 100% Ti and N.

In certain embodiments, TiN film has a Ti:N ratio selected from the group consisting of about 2.7:4, 2.8:4, 2.9:4, 3:4, 3.1:4, 3.2:4, 3.3:4, 3.4:4, 3.5:4, 3.6:4, 3.7:4, 3.8:4, 3.9:4, and 4:4.

In certain embodiments, the conductive film is prepared by performing about 150 cycles of steps (a)-(b). In certain embodiments, the conductive film is prepared by performing more than about 150 cycles of steps (a)-(b). In certain embodiments, the conductive film is prepared by performing less than about 150 cycles of steps (a)-(b).

In certain embodiments, the conductive film has a thickness selected from the group consisting of about 60, 61, 62, 63, 64, 65, 66, 67, 68, 69, and about 70 Å. In certain embodiments, the conductive film has a thickness less than about 60 Å. In certain embodiments, the conductive film has a thickness which is greater than about 70 Å.

In certain embodiments, the conductive film has a resistivity of about 110, 115, 120, 125, 130, 135, 145, 150, 155, and about 160 μΩ·cm. In certain embodiments, the conductive film has a resistivity less than about 110 μΩ·cm. In certain embodiments, the conductive film has a resistivity which is greater than about 160 μΩ·cm.

In certain embodiments, the conductive film is prepared by performing about 200 cycles of steps (a)-(b). In certain embodiments, the conductive film is prepared by performing less than about 200 cycles of steps (a)-(b). In certain embodiments, the conductive film is prepared by performing more than about 200 cycles of steps (a)-(b).

In certain embodiments, the conductive film has a thickness of about 125, 126, 127, 128, 129, 130, 131, 132, 133, 134, and about 135 Å. In certain embodiments, the conductive film has a thickness of less than about 125 Å. In certain embodiments, the conductive film has a thickness of more than about 135 Å.

In certain embodiments, the conductive film has a resistivity of about 120, 125, 130, 135, 140, 145, and about 150 μΩ·cm. In certain embodiments, the conductive film has a resistivity of less than about 120 μΩ·cm. In certain embodiments, the conductive film has a resistivity which is greater than about 150 μΩ·cm.

### Electron-Enhanced Chemical Vapor Deposition (EE-CVD)

The disclosure provides a method of promoting nucleation and/or growth of a conductive film on a solid substrate.

In certain embodiments, the method comprises contacting at least a portion of a surface of the solid substrate with a volatile metal precursor in the presence of a background gas.

In certain embodiments, the volatile metal precursor is chemisorbed or physisorbed to at least a portion of the surface of the solid substrate to provide a metal precursor-adsorbed substrate surface.

In certain embodiments, the contacting occurs with simultaneous exposure of the volatile metal precursor, background gas, and/or volatile metal precursor-adsorbed substrate surface to an electron beam.

In certain embodiments, the volatile metal precursor is an amide or imide of Be, Sc, Ti, V, Cr, Mn, Fe, Co, Ni, Cu, Zn, Al, Si, Ga, Ge, As, Se, Y, Zr, Nb, Mo, Sn, Sb, Te, La, Hf, Ta, W, Pb, or Bi. In certain embodiments, the volatile metal precursor is a halide of B, C, Al, Si, P, Ti, V, Cr, Mn, Cu, Zn, Ga, Ge, Zr, Hb, Mo, Cd, In, Sn, Sb, Hf, Ta, W, or Pb. In certain embodiments, the volatile metal precursor is an alkyl of B, Al, Si, Zn, Ga, Ge, Cd, In, Sn, Sb, Te, Hg, or Bi. In certain embodiments, the volatile metal precursor is an alkoxide of B, Al, Si, Ti, V, Ni, Ge, Zr, Nb, Hf, Ta, or Gd. In certain embodiments, the volatile metal precursor is a cyclopentadienyl of Mg, Ca, Sc, Ti, Mn, Ge, Co, Ni, Sr, Y, Zr, Ru, In, Ba, La, Hf, or Pt. In certain embodiments, the volatile metal precursor comprises a beta-diketonate or amidinate.

In certain embodiments, the metal is selected from the group consisting of Ti, Ta, W, Mo, Zr, Hf, Zn, Sc, Nb, Cu, Ni, Pt, Ru, Ni, and Al. In certain embodiments, the metal-halogen complex includes a metal selected from the group consisting of Ti, Ta, W, Mo, Zr, Hf, Zn, Sc, Nb, Cu, Ni, Pt, Ru, Ni, or Al. In certain embodiments, the metal-organic complex includes a metal selected from the group consisting of Ti, Ta, W, Mo, Zr, Hf, Zn, Sc, Nb, Cu, Ni, Pt, Ru, Ni, and Al.

In certain embodiments, the volatile metal precursor is tetrakis(dimethylamino)titanium (TDMAT).

In certain embodiments, the background gas has a pressure of about 1 mTorr to about 2 mTorr.

In certain embodiments, the background gas comprises at least one selected from the group consisting of a hydride gas, an oxide gas, a nitride gas, a sulfide gas, and a halide or halogen gas. In certain embodiments, the hydride gas is at least one selected from the group consisting of ammonia (NH₃), CH₄, H₂O, HF, HCl, SiH₄, PH₃, H₂S, GeH₄, AsH₃, and H₂Se. In certain embodiments, the oxide gas is at least one selected from the group consisting of O₂, O₃, H₂O₂, and H₂O. In certain embodiments, the nitride gas is at least one selected from the group consisting of N₂ and NH₃. In certain embodiments, the sulfide gas is at least one selected from the group consisting of S₈ and H₂S. In certain embodiments, the halide or halogen gas is at least one selected from the group consisting of F₂, HF, SF₆, NF₃, BF₃, C₁₂, HCl, BCl₃, HBr, Br₂, BBr₃, HI, and I₂.

In certain embodiments, the background gas is ammonia.

In certain embodiments, the background gas comprises a mixture of two or more distinct chemical species. In certain embodiments, the use of a background gas comprising a mixture of gases permits the deposition of ternary, quaternary, or more diverse alloy metals.

In certain embodiments, the solid substrate includes a semiconductor. In certain embodiments, the solid substrate includes a ceramic. In certain embodiments, the solid substrate includes a metal. In certain embodiments, the solid substrate includes a polymer. In certain embodiments, the solid substrate includes a metal-oxide. In certain embodiments, the solid substrate includes a mixture of any of a semiconductor, ceramic, metal, and metal-oxide.

In certain embodiments, the semiconductor includes silicon. In certain embodiments, the semiconductor is silicon nitride (Si₃N₄). In certain embodiments, the semiconductor is silicon dioxide (SiO₂). In certain embodiments, the semiconductor is crystalline silicon.

In certain embodiments, the electron beam has a current selected from the group consisting of about 0.1, 0.2, 0.3, 0.4, 0.5, 0.6, 0.7, 0.8, 0.9, 1.0, 1, 2, 3, 4, 5, 6, 7, 8, 9, 10, 11, 12, 13, 14, 15, 16, 17, 18, 19, 20, 21, 22, 23, 24, 25, 26, 27, 28, 29, 30, 31, 32, 33, 34, 35, 36, 37, 38, 39, 40, 41, 42, 43, 44, 45, 46, 47, 48, 49, 50, 51, 52, 53, 54, 55, 56, 57, 58, 59, 60, 61, 62, 63, 64, 65, 66, 67, 68, 69, 70, 71, 72, 73, 74, 75, 76, 77, 78, 79, 80, 81, 82, 83, 84, 85, 86, 87, 88, 89, 90, 91, 92, 93, 94, 95, 96, 97, 98, 99, and about 100 mA. In certain embodiments, the electron beam has a current less than about 0.1 mA. In certain embodiments, the electron beam has a current which is greater than about 100 mA.

In certain embodiments, the electron beam has an energy selected from the group consisting of about 1, 2, 3, 4, 5, 6, 7, 8, 9, 10, 11, 12, 13, 14, 15, 16, 17, 18, 19, 20, 21, 22, 23, 24, 25, 26, 27, 28, 29, 30, 31, 32, 33, 34, 35, 36, 37, 38, 39, 40, 41, 42, 43, 44, 45, 46, 47, 48, 49, 50, 51, 52, 53, 54, 55, 56, 57, 58, 59, 60, 61, 62, 63, 64, 65, 66, 67, 68, 69, 70, 71, 72, 73, 74, 75, 76, 77, 78, 79, 80, 81, 82, 83, 84, 85, 86, 87, 88, 89, 90, 91, 92, 93, 94, 95, 96, 97, 98, 99, 100, 101, 102, 103, 104, 105, 106, 107, 108, 109, 110, 111, 112, 113, 114, 115, 116, 117, 118, 119, 120, 121, 122, 123, 124, 125, 126, 127, 128, 129, 130, 131, 132, 133, 134, 135, 136, 137, 138, 139, 140, 141, 142, 143, 144, 145, 146, 147, 148, 149, and about 150 eV. In certain embodiments, the electron beam is generated using a hollow cathode plasma electron source (HC-PES).

In certain embodiments, the simultaneous exposure of the volatile metal precursor, background gas, and/or volatile metal precursor-adsorbed substrate surface to an electron beam occurs at a temperature selected from the group consisting of about 18, 19, 20, 21, 22, 23, 24, 25, 26, 27, 28, 29, 30, 31, 32, 33, 34, 35, 36, 37, 38, 39, 40, 41, 42, 43, 44, 45, 46, 47, 48, 49, 50, 51, 52, 53, 54, 55, 56, 57, 58, 59, 60, 61, 62, 63, 64, 65, 66, 67, 68, 69, 70, 71, 72, 73, 74, 75, 76, 77, 78, 79, 80, 81, 82, 83, 84, 85, 86, 87, 88, 89, 90, 91, 92, 93, 94, 95, 96, 97, 98, 99, 100, 101, 102, 103, 104, 105, 106, 107, 108, 109, 110, 111, 112, 113, 114, 115, 116, 117, 118, 119, 120, 121, 122, 123, 124, 125, 126, 127, 128, 129, 130, 131, 132, 133, 134, 135, 136, 137, 138, 139, 140, 141, 142, 143, 144, 145, 146, 147, 148, 149, and about 150° C. In certain embodiments, the simultaneous exposure of the volatile metal precursor, background gas, and/or volatile metal precursor-adsorbed substrate surface to an electron beam occurs at a temperature of less than about 18° C. In certain embodiments, the simultaneous exposure of the volatile metal precursor, background gas, and/or volatile metal precursor-adsorbed substrate surface to an electron beam steps occurs at a temperature which is greater than about 150° C.

In certain embodiments, the conductive film comprises titanium nitride (TiN).

In certain embodiments, the TiN film comprises 91%, 92%, 93%, 94%, 95%, 96%, 97%, 98%, 99%, or 100% Ti and N.

In certain embodiments, the TiN film has a Ti:N ratio selected from the group consisting of about 2.7:4, 2.8:4, 2.9:4, 3:4, 3.1:4, 3.2:4, 3.3:4, 3.4:4, 3.5:4, 3.6:4, 3.7:4, 3.8:4, 3.9:4, and 4:4.

In certain embodiments, the conductive film is prepared by performing a series of about 150 simultaneous exposures of the volatile metal precursor, background gas, and/or volatile metal precursor-adsorbed substrate surface to an electron beam. In certain embodiments, the conductive film is prepared by performing a series of more than about 150 simultaneous exposures of the volatile metal precursor, background gas, and/or volatile metal precursor-adsorbed substrate surface to an electron beam. In certain embodiments, the conductive film is prepared by performing a series of less than about 150 simultaneous exposure of the volatile metal precursor, background gas, and/or volatile metal precursor-adsorbed substrate surface to an electron beam.

In certain embodiments, the conductive film has a thickness selected from the group consisting of about 60, 61, 62, 63, 64, 65, 66, 67, 68, 69, and about 70 Å. In certain embodiments, the conductive film has a thickness less than about 60 Å. In certain embodiments, the conductive film has a thickness which is greater than about 70 Å.

In certain embodiments, the conductive film has a resistivity of about 110, 115, 120, 125, 130, 135, 145, 150, 155, and about 160 μΩ·cm. In certain embodiments, the conductive film has a resistivity less than about 110 μΩ·cm. In certain embodiments, the conductive film has a resistivity which is greater than about 160 μΩ·cm.

In certain embodiments, the conductive film is prepared by performing a series of about 200 simultaneous exposure of the volatile metal precursor, background gas, and/or volatile metal precursor-adsorbed substrate surface to an electron beam. In certain embodiments, the conductive film is prepared by performing a series of less than about 200 simultaneous exposure of the volatile metal precursor, background gas, and/or volatile metal precursor-adsorbed substrate surface to an electron beam. In certain embodiments, the conductive film is prepared by performing a series of more than about 200 simultaneous exposure of the volatile metal precursor, background gas, and/or volatile metal precursor-adsorbed substrate surface to an electron beam.

In certain embodiments, the conductive film has a thickness of about 125, 126, 127, 128, 129, 130, 131, 132, 133, 134, and about 135 Å. In certain embodiments, the conductive film has a thickness of less than about 125 Å. In certain embodiments, the conductive film has a thickness of more than about 135 Å.

In certain embodiments, the conductive film has a resistivity of about 120, 125, 130, 135, 140, 145, and about 150 μΩ·cm. In certain embodiments, the conductive film has a resistivity of less than about 120 μΩ·cm. In certain embodiments, the conductive film has a resistivity which is greater than about 150 μΩ·cm.

In certain embodiments, the film deposited by EE-ALD is a metallic film.

### Devices

In another aspect, the present invention provides a microdevice or nanodevice comprising a conductive film prepared according to the methods described herein.

In certain embodiments, the microdevice or nanodevice is selected from the group consisting of a diffusion barrier, liner, transistor, channel materials, via, conduit, and any other electrical circuit components, Josephson junction, superconducting device, electrical conductor, photovoltaic, transistor, diode, waveguide, electrical transmission line, light emitting diode, thermocouple, mirror, absorber for photons, photon emitter, radiation shield, and radiation detector.

In certain embodiments, the microdevice or nanodevice is selected from the group consisting of a bolometer, transducer, temperature sensor, heater, thermistor, microbolometer, microphone, speaker, ultrasonic transducer, resistor, inductor, spiral inductor, mechanical actuator, flagellum, flagellum motor, freestanding nanodevice, freestanding microdevice, Bragg reflector, Bragg filter, antenna, terahertz detector, electromagnetic transformer, and electrical system.

In certain embodiments, the microdevice or nanodevice is selected from the group consisting of a nanotube, nanowire, coaxial wire, hollow tube with nanoscale diameters, periodic structure, or metamaterial.

Those skilled in the art will recognize, or be able to ascertain using no more than routine experimentation, numerous equivalents to the specific procedures, embodiments, claims, and examples described herein. Such equivalents were considered to be within the scope of this invention and covered by the claims appended hereto. For example, it should be understood, that modifications in reaction conditions, including but not limited to reaction times, reaction size/volume, and experimental reagents, such as solvents, catalysts, pressures, atmospheric conditions, e.g., nitrogen atmosphere, and reducing/oxidizing agents, with art-recognized alternatives and using no more than routine experimentation, are within the scope of the present application. In general the terms and phrases used herein have their art-recognized meaning, which can be found by reference to standard texts, journal references and contexts known to those skilled in the art. Any preceding definitions are provided to clarify their specific use in the context of the invention.

### EXAMPLES

The invention is now described with reference to the following Examples. These Examples are provided for the purpose of illustration only, and the invention is not limited to these Examples, but rather encompasses all variations that are evident as a result of the teachings provided herein.

### Materials and Methods

### TiN EE-ALD Film Growth

TiN EE-ALD films were grown in a vacuum chamber that has been described previously. The main UHV chamber had a base pressure of 2×10⁻⁹ Torr. This chamber was equipped with a load lock that allowed samples to be introduced without breaking vacuum. The main chamber also contained an in situ ellipsometer (Filmsensel) and mass spectrometer (PrismaPlus QMG 220, Pfeiffer Vacuum). The chamber was also equipped with a cold cathode gauge (MKS) to measure pressure. In addition, a pico-ammeter (Keithley) was attached to the sample stage to measure the incident electron current from the electron source.

TiN EE-ALD growth was conducted using a pulse sequence consisting of: (1) TDMAT dose; (2) pump time; (3) electron beam exposure; and (4) pump time before the next TDMAT dose. The timing for this pulsing sequence can be characterized by (t₁, t₂, t₃, t₄). For deposition on the silicon native oxide and the SiO₂ thermal oxide, the TDMAT precursor was maintained at P=0.3 Torr behind a micropulse valve. The valve was actuated for t₁=1 s. The valve opening led to a transient pressure in the main chamber of 4×10⁻⁷ Torr as measured by the cold cathode gauge. The pressure at the sample was higher because the micropulse valve was connected to a ¼″ diameter tube that led to the sample and ended ˜5 cm from the sample. For deposition on the in situ deposited Si₃N₄, the valve was actuated for 2 s. The TDMAT pressure was 0.2 Torr behind the micropulse valve. These conditions yielded a transient pressure of 6×10⁻⁷ Torr.

Pumping was then performed for a total of t₂=2 s. Subsequently, the electron exposure was performed with a grid bias of 100 V for t₃=20 s, with an electron current measured at the sample stage of −25 mA. The next TDMAT adsorption was then conducted after a pump time of t₄=1 s. The timing for this pulsing sequence was (1, 2, 20, 1). The sum of these steps produced a reaction cycle time of ˜24 seconds. The NH₃ (Matheson, 99.9992%) RBG was flowed into the chamber though a leak valve and produced an increase in the reactor pressure of −1 mTorr as measured by the cold cathode pressure gauge (MKS) for the entirety of the experiment

### Electron Source

The electron source was a hollow cathode plasma electron source (HC-PES) that has been previously described. An argon (Airgas, 99.999%) plasma was sparked in the hollow cathode body. Low energy electrons were extracted with a biased grid. The electrons exited the HC through an aperture. Argon gas also leaked through this aperture and produced a pressure of ˜1 mTorr in the reactor. All the work in this study used an applied voltage of 100 V to the biased grid. This applied voltage accelerated the electrons leaving the aperture. The electrons were separated from any sputtered material from the HC-PES using electron optics. An analysis chamber containing an in vacuo Auger electron spectroscopy (AES) spectrometer (RBD, microCMA) was also attached to the main chamber.

### Reactive Background Gas (RBG)

An NH₃ RBG (Matheson, 99.9992%) was present continuously during the TiN EE-ALD. The NH₃ RBG pressure was ˜1 mTorr. The recommended total cross section for electron scattering in NH₃ is 6=8.57×10⁻¹⁶ cm² for electron energies of 100 eV. In addition, the Ar pressure was ˜1 mTorr. The total cross section for electron scattering in Ar is σ˜8×10⁻¹⁶ cm² for electron energies of 100 eV. The mean free path for electrons traveling through gas is λₑ=1/ρσ where ρ is the gas number density and 6 is the cross section for electron scattering from the gas. The gas number density is 6=3.2×10¹³ molecules/cm³ at a pressure of 1 mTorr for both Ar and NH₃. Therefore, the electron mean free path is λₑ=18 cm using σ˜8×10⁻¹⁶ cm² for the Ar and NH₃ total cross sections. Electron scattering by the Ar and NH₃ RBG does not seriously affect the electron transport over the 25 cm distance between the HC-PES and the sample.

### Substrates

TiN EE-ALD can be performed using any of a number of substrates, non-limiting examples including silicon coupons and silicon nitride. For example, substrates may include silicon coupons containing a native oxide, an SiO₂ thermal oxide, and in situ deposited silicon nitride. The Si wafer coupons (Silicon Valley Microelectronics, boron-doped) contained a native oxide on the silicon surface. The SiO₂ thermal oxide had a thickness of 400 nm on a Si wafer. Prior to insertion into the vacuum apparatus, the coupons were washed sequentially in methanol, acetone, and DI water, then blown dry with ultra-high purity nitrogen. The coupons were then loaded into the load lock chamber following procedures that have been previously described.

Si₃N₄ substrates have also been employed using the methods described herein. In situ deposited Si₃N₄ films were grown using pulsed electron-enhanced chemical vapor deposition (EE-CVD). For this Si₃N₄ pulsed EE-CVD, an NH₃ RBG was flowed through the chamber during continuous electron beam irradiation of the sample. Throughout this continuous electron beam and NH₃ exposure, Si₂H₆ was pulsed into the chamber every 5 seconds. In situ ellipsometry measurements observed that the Si₃N₄ films nucleated on the first Si₂H₆ pulse and grew linearly versus number of Si₂H₆ exposures. The Si₃N₄ pulsed EE-CVD films were grown to a thickness of ˜10 nm. The Si₃N₄ pulsed EE-CVD films had high purity as measured by in vacuo AES. The films displayed a nearly stoichiometric 3:4 Si:N ratio with C and O impurities <2 at %. In addition, the Si₃N₄ pulsed EE-CVD films were smooth as measured by ex situ AFM with an RMS roughness of <2 Å.

### In Situ Ellipsometry

In situ ellipsometry measurements were collected every second throughout the deposition. The in situ ellipsometer uses four wavelengths of light. The precision of the in situ ellipsometry measurements of film thickness was within ±0.03 Å. The in situ ellipsometer used a Drude-Lorentz model to model the TiN films. The Filmsense software was able to extrapolate resistivity from the model. Ex situ spectroscopic ellipsometry (Model M-2000, J.A. Woollam Co., Inc.) was also performed to measure the film thickness of some samples after taking them from the reactor. The data was fit using a Drude-Lorentz model with a Drude oscillator (119 μΩ·cm resistivity, 0.952 fs scattering time) and one Lorentzian oscillator (energy: 5.385 eV, amplitude: 6.519, broadening: 3.980 eV).

### Ex Situ Resistivity Measurements

A four-point probe (Signatone, QP2-MB8) was used for ex situ resistivity measurements. The probe spacing was 1 mm. The geometric correction factor was chosen based on the ratio of the probe spacing to the diameter of the largest inset circle possible on the wafer coupon. A typical geometric correction factor was 0.92. AFM measurements were used to monitor ex situ film roughness. The AFM measurements were performed with a Park NX10 AFM instrument using non-contact mode. The scan rate was 0.3-0.8 Hz for a 1×1 m area using an Olympus micro cantilever probe (OMCL-AC160TS).

### X-Ray Reflectivity (XRR)

X-ray reflectivity (XRR) was used to determine film thickness and density. Grazing incidence x-ray diffraction (GI-XRD) determined crystallinity of the films. Both GI-XRD and XRR scans were performed using a Bede D1 from Jordan Valley Semiconductors with radiation from Cu Kα (λ=1.540 Å). The X-ray tube filament voltage was 40 kV and the current was 35 mA. The incident angle used for GI-XRD was 0.3°. The XRR scan range was 300 to 6000 arcsec with a 5 arcsec step size. The modeling software for the XRR scans was REFS by Jordan Valley Semiconductors.

### Example 1: Method of Preparing Titanium Nitride (TiN) Films by Electron-Enhanced Atomic Layer Deposition (EE-ALD)

TiN films were grown on various substrates, including silicon nitride (Si₃N₄) and Si wafer coupons, wherein the silicon coupons contained the native oxide on the surface. In certain embodiments, the substrates were washed with isopropyl alcohol, acetone, rinsed in deionized water, and blown dry with ultrahigh purity N₂ gas. Once dried, the substrates were subsequently loaded into the load lock chamber.

Each cycle of TiN EE-ALD nucleation and/or growth was conducted using a pulse sequence comprising: (1) TDMAT; (2) pump; (3) electron beam exposure; and (4) pump.

Tables 1-2 of the present disclosure provide parameters for EE-ALD, according to various embodiments.

TABLE 1
Non-limiting conditions for alternate dose

| No. of | | | | |
|---|---|---|---|---|
| Cycles | Precursor Dose | Pump 1 | Electron Exposure | Pump 2 |
| 100 | 2000 ms, 0.2 Torr | 2 s | 20 s, 18 mA | 1 s |

TABLE 2
Non-limiting conditions for co-dose

| No. of | | | | |
|---|---|---|---|---|
| Cycles | Precursor Dose | Pump | Electron Exposure | Pump 2 |
| 50 | 200 ms, 2.0 Torr | 2 s | constant, 20 mA | — |

### Example 2: Preparation and Characterization of TiN EE-ALD Films on a Silicon Nitride (Si₃N₄) Substrate

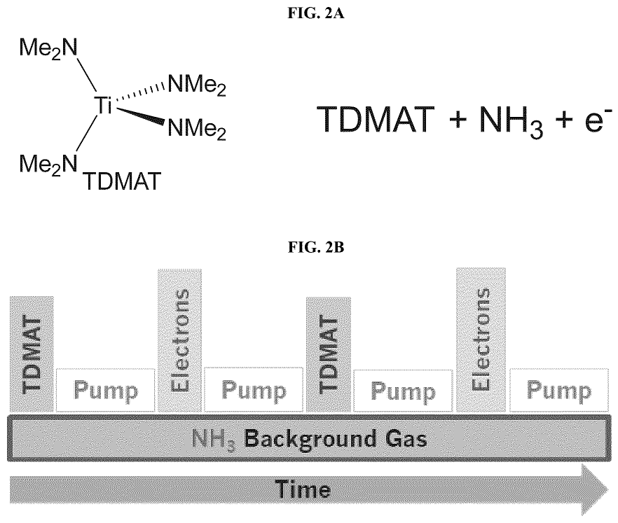

In certain embodiments, TiN EE-ALD films were prepared, by alternate dosing of step (a) and step (b) on a silicon nitride substrate, wherein thickness was monitored by ellipsometry (FIGS. 2A-2B). The in situ deposited Si₃N₄ films were grown using pulsed electron-enhanced chemical vapor deposition (EE-CVD). For this Si₃N₄ pulsed EE-CVD, a NH₃ background was flowed through the chamber during electron beam irradiation of the sample. Throughout this continuous electron beam and NH₃ exposure, Si₂H₆ was pulsed into the chamber every 5 seconds.

In situ ellipsometry measurements indicated that the Si₃N₄ films nucleated on the first Si₂H₆ pulse and grew linearly versus number of Si₂H₆ exposures. The Si₃N₄ pulsed EE-CVD films were grown to a thickness of ˜10 nm. The Si₃N₄ pulsed EE-CVD films had high purity as measured by in vacuo AES. The films displayed a nearly stoichiometric 3:4 Si:N ratio with C and O impurities at <2%. In addition, the Si₃N₄ pulsed EE-CVD films were smooth, as measured by ex situ AFM with an RMS roughness of <2 Å.

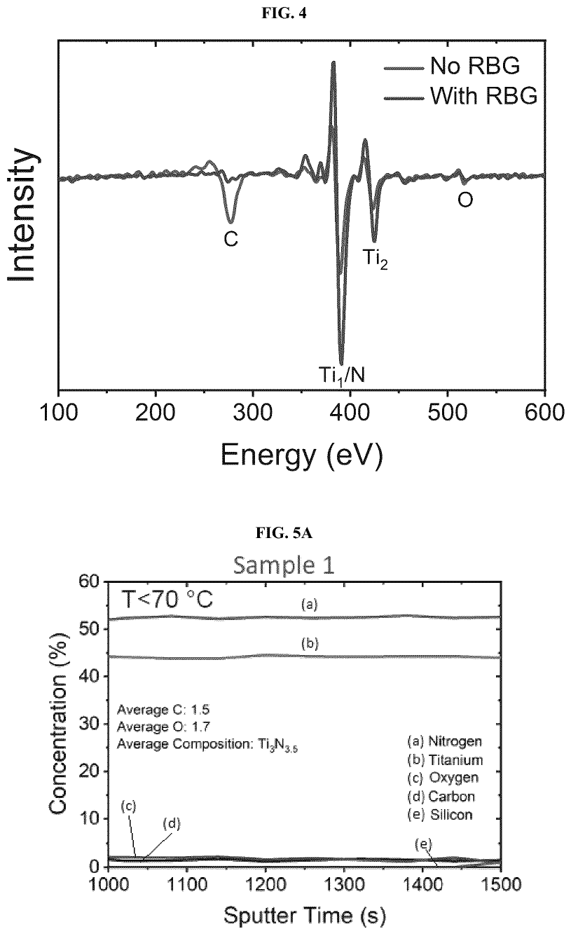

Linear TiN EE-ALD film growth was observed on the Si₃N₄ substrate after approximately 7 EE-ALD cycles with a growth rate of 1.8/cycle. The TiN film described herein was analyzed by Auger electron spectroscopy (AES), wherein a high purity of TiN was observed (i.e., approximately 92% Ti+N) (FIG. 4). Without the background gas, the TiN EE-ALD film was contaminated with carbon.

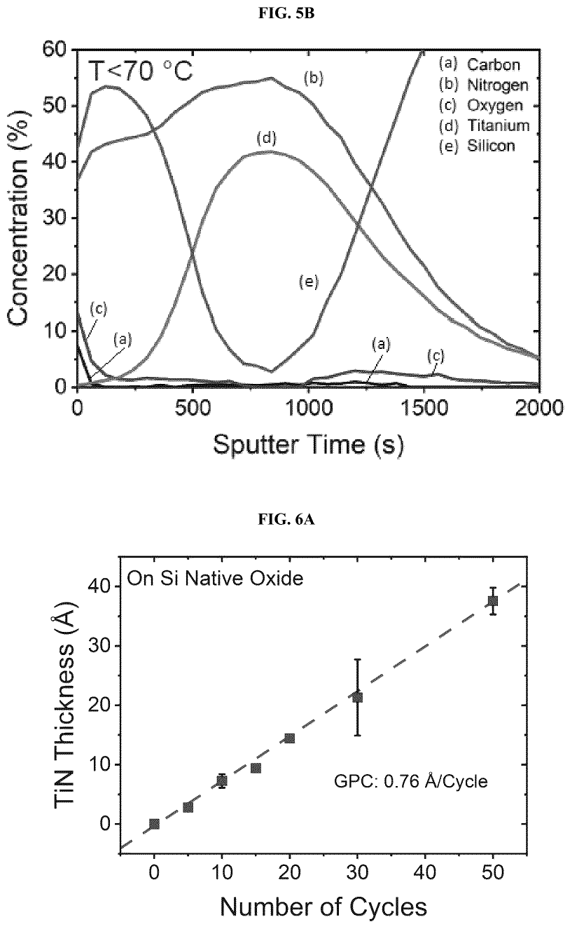

A high purity was also observed with analysis of the TiN flm by x-ray photoelectron spectroscopy (XPS) (FIGS. 5A-5B), wherein <3% C+O was observed.

### Example 3: Preparation and Characterization of TiN EE-ALD Films on a Silicon Wafer and/or Thermal Oxide Substrate(s)

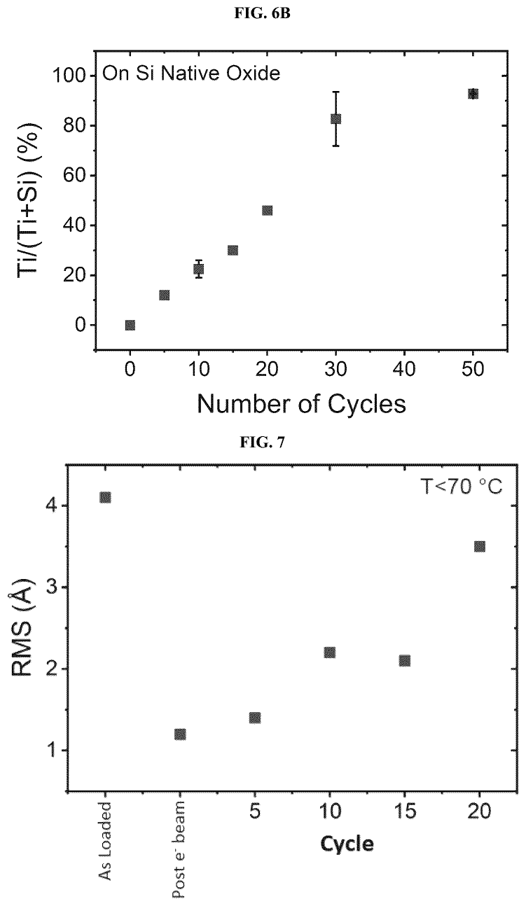

Ten separate TiN EE-ALD films were prepared, by alternate dosing of step (a) and step (b) on a silicon wafer substrate, wherein the number of EE-ALD cycles were varied (i.e., 0, 5, 10, 15, 20, 30, and 50 cycles). Both the ellipsometry (FIG. 6A) and AES (FIG. 6B) results show the rapid nucleation of the TiN EE-ALD film. The TiN films described herein were analyzed by ellipsometry (FIG. 6A) and AES (FIG. 6B).

Film roughness for these samples was measured by AFM as a function of number of EE-ALD cycles. The films were measured after exposure to the first electron beam and then again after various numbers of EE-ALD cycles up to 50 cycles. The RMS roughness increased slightly and then leveled out at an RMS roughness of ˜3.5 Å. It was further observed that the roughness of the initial sample was high (i.e., ˜4 Å) prior to a 5 min exposure of the electron beam with a ˜1 mTorr NH₃ background. Without wishing to be bound by theory, the decrease in roughness may be a result of cleaning of the initial Si native oxide by the interaction of the electron beam with the NH₃ RBG to produce radicals which desorb adventitious surface carbon.

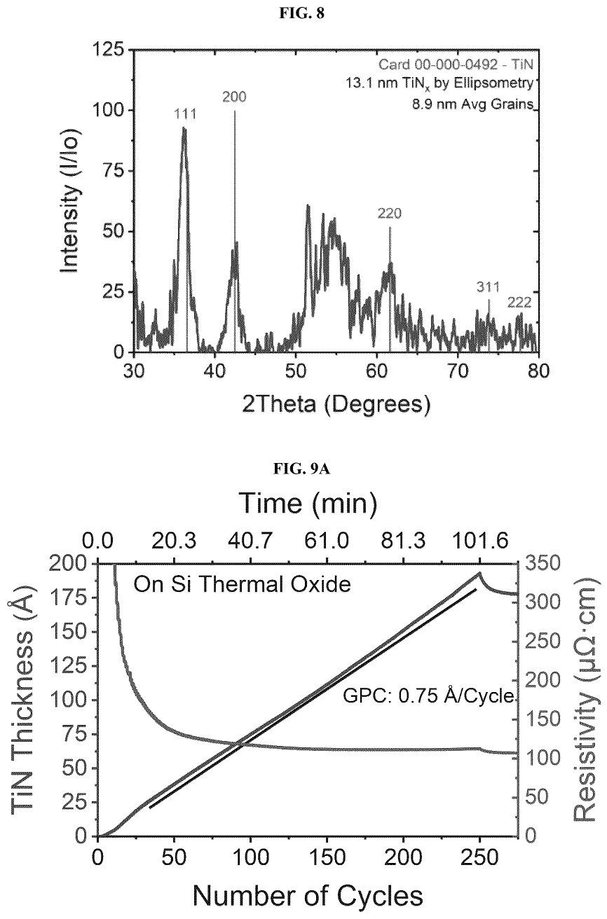

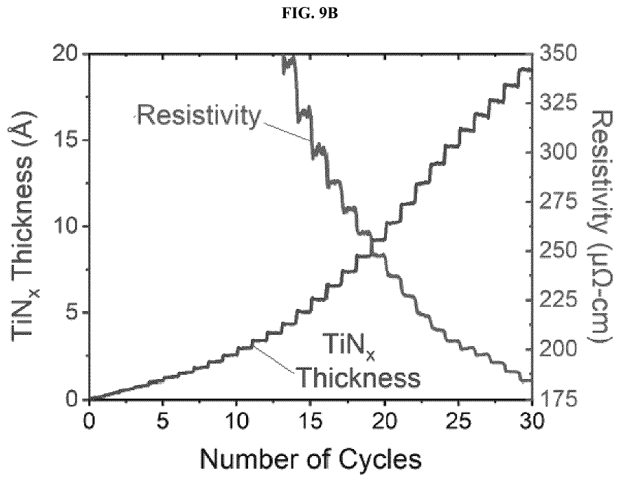

TiN EE-ALD films were prepared, by alternate dosing of step (a) and step (b) on a Si thermal oxide substrate. The TiN films described herein were subject to various analyses, including ellipsometry, x-ray reflectometry (XRR), resistivity measurements, and x-ray diffraction (Tables 3-5, FIG. 8, and FIGS. 9A-9B).

TABLE 3
Ellipsometry measurements for samples 056 and 057

| | In situ Thickness | Ex situ Thickness |
|---|---|---|
| Sample | (Å) | (Å) |
| 056 | 75 | 89 |
| 057 | 133 | 129 |

TABLE 4
XRR measurements for samples 056 and 057

| | TiNₓ Thickness | TiNₓ Density | TiNₓ Roughness |
|---|---|---|---|
| Sample | (Å) | (%) | (Å) |
| 056 | 64 | 98 | 10 |
| 057 | 111 | 99 | 12 |

TABLE 5
EE-ALD film parameters and electrical measurements thereof

| | | | Growth | 4PP | Ex situ | In situ |
|---|---|---|---|---|---|---|
| | No. | Thick- | per | Resis- | Resis- | Resis- |
| Sam- | of | ness | Cycle | tivity | tivity | tivity |
| ple | Cycles | (Å) | (Å/cycle) | (μΩ · cm) | (μΩ · cm) | (μΩ · cm) |
| 056 | 150 | 82 | 0.55 | 148 ± 14 | 130 | 118 |
| 057 | 200 | 132 | 0.66 | 135 ± 39 | 119 | 118 |
| 058 | 250 | 173 | 0.69 | 131 ± 8 | 125 | 105 |

In certain embodiments, the TiN films described here demonstrate superior resistivity (i.e., low resistivity) over other films described in the literature, including thin films prepared by thermal ALD, including Wolf et al. (Applied Surface Science 2018, 462:1029-1035), Stevens et al. (Chem. Mater. 2018, 30:3223-3232), Lee et al. (doi:10.1021/acsaelm.0c01079), J. W. Elam et al. (Thin Solid Films 2003, 436:145-156), Wang et al. (ECS Transactions 2009, 22(1):167-173), and Kuo et al. (doi:10.1109/IITC51362.2021.9537463), or by plasma-enhanced ALD, including Chen et al. (doi:10.1051/matecconf/20163901010) and Musschoot et al. (doi:10.1016/j.mee.2008.09.036), which would not have been expected by one skilled in the art (FIGS. 11A-11B).

### Example 4: Nucleation Regime for TiN EE-ALD

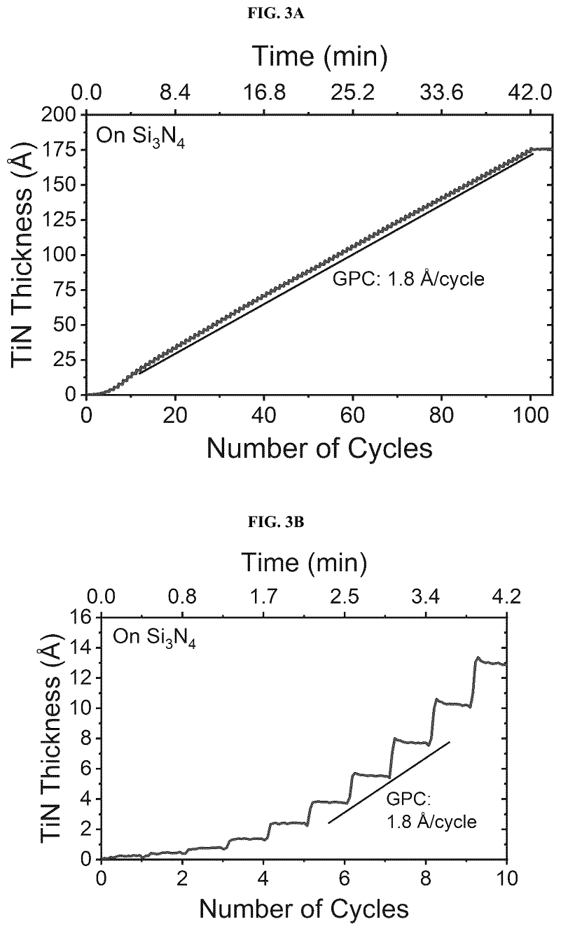

The TiN EE-ALD films grown in the presence of the NH₃ RBG nucleated rapidly on the Si native oxide, thermal SiO₂ and the in situ deposited Si₃N₄ EE-CVD films. FIG. 3A displays the growth of a TiN EE-ALD film on an in situ deposited Si₃N₄ EE-CVD film. These in situ ellipsometry measurements were performed in real time during the TiN EE-ALD. The pulsing sequence in seconds was (2, 2, 20, 1) with a NH₃ RBG of ˜1 mTorr and a pressure of 0.2 Torr behind the micropulse valve. The TDMAT exposures produced a pressure transient of 6×10⁻⁷ Torr in an empty reactor. FIG. 3A shows that the TiN EE-ALD film nucleates quickly and then grows with a growth per cycle (GPC) of 1.8/cycle. An expansion of the first 10 EE-ALD cycles from the ellipsometric results in FIG. 3A is provided in FIG. 3B. The TiN EE-ALD reaches the GPC of 1.8/cycle after only 6-7 cycles.

Additional experiments determined that the TiN EE-ALD growth rates were dependent on the TDMAT precursor exposures. At higher TDMAT precursor exposures, the GPCs could reach >5 Å/cycle. These larger GPCs could be explained by larger TDMAT coverages adsorbed on the growing TiN surface after higher TDMAT exposures. Earlier experiments have confirmed that TDMAT adsorbs with a coverage-dependent sticking coefficient on TiN surfaces. The adsorbed TDMAT then slowly desorbs with a coverage-dependent desorption rate.

There also may be partial decomposition of TDMAT on electron-activated substrates through a mechanism like autocatalytic deposition. This mechanism could lead to the buildup of thick films with partially decomposed TDMAT precursors. To avoid these larger GPCs and higher carbon impurities in the TiN EE-ALD film, the results described herein were obtained with shorter TDMAT precursor exposures of 1 s with TDMAT pressures of 0.30 Torr behind the micropulse valve. These TDMAT exposures produced a pressure transient of 4×10⁻⁷ Torr in an empty reactor.

The TiN EE-ALD films grown using the NH₃ RBG also nucleated rapidly on the Si native oxide. FIG. 6A displays the TiN thickness versus number of EE-ALD cycles. The dosing sequence was (1-2-20-1) with a pressure of 0.30 Torr behind the micropulse valve. Each data point represents a separate sample. The samples were removed from the reactor after a certain number of EE-ALD cycles for subsequent analysis. The TiN thickness increased linearly with increasing number of cycles with a GPC of 0.76/cycle. The GPC was lower because the TDMAT exposure was lower compared with the TDMAT exposures employed for FIGS. 3A-3B. A linear regression through the values for the TiN thickness versus number of EE-ALD cycles showed that the x-intercept was at 1 EE-ALD cycle. This x-intercept is interpreted as a nucleation delay of 1 EE-ALD cycle.

The nucleation of TiN EE-ALD on Si native oxide was also explored using in vacuo AES after various numbers of EE-ALD cycles. These AES results are for the same set of samples as shown in FIG. 6A. After each TiN deposition, the main chamber was pumped down to ˜1×10⁷ Torr. The sample was then transferred to the AES chamber. This process was repeated for 5, 10, 15, 20, 30 and 50 TiN EE-ALD cycles.

FIG. 6B shows the results for the Ti/(Ti+Si) ratio of AES signals versus number of EE-ALD cycles. The Ti/(Ti+Si) ratio of AES signals increases linearly with increasing number of cycles over the first 30 EE-ALD cycles. After ˜30 EE-ALD cycles, the Ti and Si AES signals reach limiting values because of the finite mean free path for the Auger electrons in the TiN film. The Ti AES signal reaches the limiting value for a bulk TiN film. The Si AES signal becomes completely attenuated by the overlying TiN film. The limiting value for the Ti/(Ti+Si) ratio at values slightly less than 100% can be explained by noise in the AES spectrum near the Si peak that leads to a finite apparent Si AES signal.

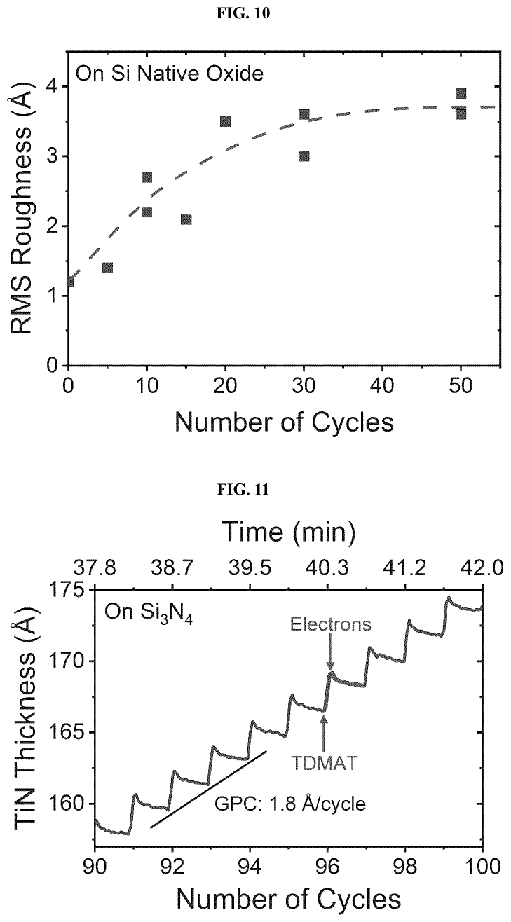

The roughness of the TiN EE-ALD films in the initial nucleation region on the Si native oxide was also studied by ex situ AFM measurements. Surface roughnesses were obtained for separate samples coated with 5, 10, 15, 20, 30, and 50 cycles of TiN EE-ALD. FIG. 10 displays the RMS values measured by the AFM versus number of EE-ALD cycles. The RMS roughness for a bare, cleaned Si coupon is ˜4 Å. After a 5-minute electron exposure with NH₃ RBG to mimic the TiN EE-ALD reaction conditions, the RMS roughness drops to ˜1 Å. This RMS roughness was used for the RMS roughness at 0 cycles of TiN EE-ALD. The RMS roughness then increases slowly by ˜3 Å over 50 EE-ALD cycles. The resulting RMS surface roughness reaches a limiting value at ˜4 Å.

The change in the surface roughness of the Si native oxide resulting from the initial 5-minute electron exposure with NH₃ RBG motivated a study of the change in surface composition using in vacuo AES. One Si native oxide sample was loaded and irradiated with the electron beam and exposed to the NH₃ RBG for 5 minutes with an electron sample current of 20 mA as a control. This control sample showed ˜40 at % N on the surface by in vacuo AES. This N AES signal likely results from surface nitridation by •NH₂ species from the electron beam interaction with the NH₃ RBG. In addition, the oxygen and carbon AES signals decreased by factors of 2.7 and 2.3, respectively, relative to initial Si native oxide samples that were not subjected to the electron exposures with NH₃ RBG. These experiments suggest that surface cleaning and smoothing results from the electron exposures with NH₃ RBG.

### Example 5: Steady State Growth for TiN EE-ALD

In situ ellipsometry was used to monitor the TiN EE-ALD in the steady state growth regime using sequential exposures of TDMAT and electrons with a NH₃ RBG in the chamber as shown in FIGS. 2A-2B. FIG. 11 shows the results for 10 cycles during 90-100 EE-ALD cycles on the in situ grown Si₃N₄ EE-CVD film. The dosing sequence was (2-2-20-1) with a pressure of 0.20 Torr behind the micropulse valve. The film thickness increases resulting from TDMAT adsorption during the TDMAT exposures. During the electron exposure, the TiN thickness decreases resulting from the ESD of surface species. Without wishing to be bound by theory, the surface species may be the dimethylamine ligands on the TDMAT adsorption products.

Initially the thickness decreases quickly during the electron exposure. Subsequently, there is a slow decrease of the thickness. This slow decrease may be the additional loss of dimethylamine ligands or removal of fragmented dimethylamino ligands by the NH₃ RBG. An electron exposure of 20 s was chosen because shorter electron exposures led to a higher C content in the films. The effect of the electron beam exposure time had a dramatic effect on the purity of the TiN film.

FIG. 4 shows the in vacuo AES results for TiN EE-ALD with and without the NH₃ RBG. The TiN EE-ALD film grown with no NH₃ RBG used 27 EE-ALD cycles. The dosing sequence was (2-2-20-1) with a pressure of 0.20 Torr behind the micropulse valve. The NH₃ TiN EE-ALD film grown with the NH₃ RBG utilized 50 EE-ALD cycles. Without an NH₃ RBG, the in vacuo AES measured a C content in the as-deposited TiN film of ˜60 at %. In contrast, with the NH₃ RBG, the C content in the as-deposited TiN film was ˜3 at %. These results illustrate that the NH₃ RBG greatly enhances the purity of the TiN EE-ALD films.

In vacuo AES measurements also confirmed that the TiN EE-ALD films deposited with larger TDMAT precursor exposures contained more carbon. With the electron exposure held constant, the carbon content in the film increased for these larger TDMAT precursor exposures. Carbon compositions of >30 at % were observed when the TiN EE-ALD growth per cycle was 7 Å/cycle. These larger carbon contents were obtained with a TDMAT precursor exposure of 1 s with TDMAT pressure behind the micropulse valve of >0.60 Torr.

Grazing incidence x-ray diffraction (GI-XRD) was used to determine the crystallinity of the TiN EE-ALD films. Despite low growth temperatures <70° C., the TiN films display crystallinity. The GI-XRD results are displayed in FIG. 8 for a TiN EE-ALD film with a thickness of 13.1 nm deposited on Si thermal oxide using 200 EE-ALD cycles. The dosing sequence was (1-2-20-1) with a pressure of 0.30 Torr behind the micropulse valve. The <111> and <200> peaks of crystalline TiN match the diffraction peaks in FIG. 8. The <220>, <311>, and <222> peaks of crystalline TiN are also discernable above baseline. The Scherrer equation yields an average grain size of 8.9 nm for all 5 fitted peaks. The broad peak at 2θ˜55° is attributed to the <311> planes in crystalline silicon.

X-ray reflectometry (XRR) was also used to measure the density of the TiN EE-ALD films. The average density of the films was 5.3 g/cm³. This density is 98.5±0.5% of theoretical TiN bulk density of 5.4 g/cm³. Without wishing to be bound by theory, this high density suggests that these TiN films will be resistant to oxidation. This oxidation resistance has been confirmed by the depth profile XPS measurements where there is minimal O diffusion into the TiN films. This behavior is in contrast to thermal TiN ALD films that display high porosity leading to facile oxidation.

### Example 6: Mechanism for TiN EE-ALD with NH₃ Reactive Background Gas

The TiN EE-ALD grown with the NH₃ RBG at <70° C. have high purity, high density, and crystallinity. The NH₃ RBG is facilitating the growth of these films. An illustration of TiN EE-ALD using TDMAT and low energy electrons in the presence of a continuous NH₃ RBG is shown in FIG. 1. The electrons are believed to play a key role by dissociating NH₃ in the gas phase to produce •NH₂ and •H radicals. These radicals can adsorb onto empty sites on the TiN surface. In addition, these radicals can abstract dimethylamino ligands from TDMAT adsorption products on the surface.

In addition to dissociating NH₃ in the gas phase, the electrons can also desorb H from —NH₂ species on the surface. This H ESD produces additional empty sites on the TiN surface. The TDMAT precursor can then adsorb onto these empty sites to add more Ti to the TiN surface. The electrons may also crack dimethylamino ligands on the surface and produce carbon fragments. However, the continuous flux of •NH₂ and •H radicals from NH₃ dissociation may be able to remove this surface carbon as CH₄ or CH₃NH₂. The •H radicals may also provide a pathway for the removal of oxygen impurities as H₂O.

The primary motivation for introducing the NH₃ RBG was to ensure the complete nitridation of the TiN film. The effect of the NH₃ RBG on the film purity was an unexpected result that is attributed to the cleaning effect of the •NH₂ and •H radicals. In addition, the possibility of introducing various RBGs offers a new parameter to tune the composition of EE-ALD films. Different films can be deposited from a single metal precursor, such as TDMAT, by changing the RBG. For example, the dissociation or adsorption of NH₃, Si₂H₆, CH₄, or B2H₆ RBGs should form nitrides, silicides, carbides, or borides, respectively, with the metal precursor. The single RBG can also be extended to two or three RBGs to deposit ternary or quaternary EE-ALD films.

### Example 7: Resistivity of TiN EE-ALD Films

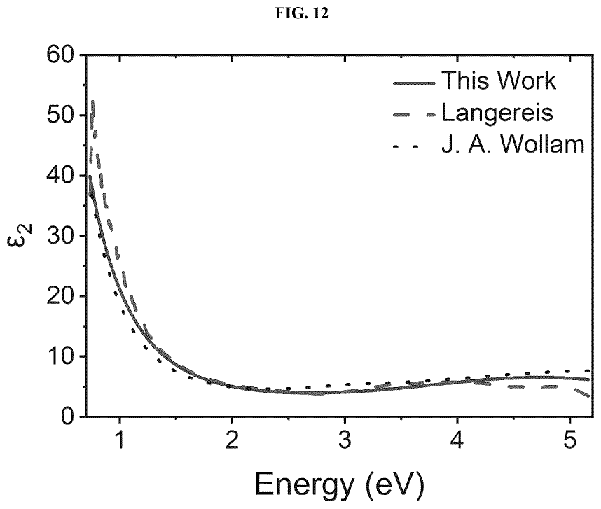

The resistivity of the TiN EE-ALD films was characterized using in situ 4 wavelength and ex situ spectroscopic ellipsometry. To confirm that the TiN EE-ALD films were comparable with other TiN films, FIG. 12 shows the results for the imaginary part of the pseudo dielectric function (ε₂) for the TiN EE-ALD films, TiN plasma-enhanced ALD (PE-ALD) films reported in the literature, and TiN films reported in the J.A. Woollam CompleteEASE database. The results shown for the TiN EE-ALD film were obtained using ex situ spectroscopic ellipsometry. FIG. 12 shows that there is excellent agreement between these three data sets. In particular, there is a good correlation at low energy where the Drude term in the ellipsometry model is related to the film resistivity. The good agreement between the ellipsometry model used herein and the available literature models suggests both that the model used herein is accurate and the TiN EE-ALD film is high quality TiN.

The in situ ellipsometry results for the thickness and resistivity of a TiN EE-ALD film is shown in FIG. 9A. These results are for TiN EE-ALD on a Si thermal oxide with a thickness of 400 nm. The dosing sequence was (1-2-20-1) with a pressure of 0.30 Torr behind the micropulse valve. Similar to the results described elsewhere herein, there is rapid nucleation of the TiN EE-ALD film. The TiN film then grows linearly with a GPC of 0.75 Å/cycle over 250 EE-ALD cycles. FIG. 9A also shows the corresponding resistivity of the TiN film determined from the Drude term in the ellipsometry model.

The film resistivity drops rapidly in the nucleation regime during the first 12-13 cycles. These resistivities are artificially low for film thicknesses <4 nm resulting from the inability of ellipsometry to fully account for electron scattering at grain boundaries and interfaces. The film resistivity continues to decrease progressively and reaches a resistivity of ˜130 μΩ·cm after 50 cycles at a film thickness of ˜4 nm. The resistivity continues to decrease slowly as the film thickness increases to ˜185 Å where the resistivity is ˜110 μΩ·cm after 250 cycles.

The EE-ALD is stopped after 250 cycles. Without the electron current impinging on the sample, the film begins to cool slightly from −65° C. over the next ˜10 minutes. This cooling results in a decrease in the model film thickness of ˜16 Å and a corresponding decrease in resistivity to 104 μΩ·cm. The decrease in the model film thickness is associated with the temperature change of the film. The electronic properties change with temperature. The ellipsometry model interprets this temperature change as a change in film thickness.

The TiN EE-ALD film after 250 cycles in FIG. 9A was also characterized by ex situ spectroscopic ellipsometry. The thickness for this film was calculated to be 173 Å from a 9 point map over a 1.5×1.5 cm area of the sample. This thickness is in good agreement with the thickness of 169 Å determined by the in situ ellipsometry after the sample cooled following the electron exposure. The Drude-Lorentz model used for the ex situ spectroscopic ellipsometry over the same 9 points gave a resistivity of 125 μΩ·cm. This resistivity is also in good agreement with the resistivity of 104 μΩ·cm determined by the in situ ellipsometry.

Four-point probe measurements were also employed to corroborate the resistivity measurements from ellipsometry. A geometric correction factor of 0.92 was applied to the raw resistivity data to account for the small coupon size. A resistivity of 131 μΩ·cm was obtained from 10 locations at the center of substrate immediately after removal from the deposition chamber. This resistivity is also in good agreement with the resistivity from the ellipsometry measurements. There was a negligible increase in resistivity from the four-point probe measurement over a 24 hour period after removing the film from vacuum. No increase in resistivity after prolonged air exposure suggests a dense TiN film that is resistant to oxidation.

Additional experiments were conducted on a 400 nm Si thermal oxide with 150 and 200 TiN EE-ALD cycles. These experiments were performed using the same reactions as employed for the 250 TiN EE-ALD cycles shown in FIG. 9A. The results from the in situ ellipsometry, ex situ spectroscopic ellipsometry and four-point probe measurements are given in Table 5. There is good agreement between all the resistivity values indicating that the in situ ellipsometry results shown in FIG. 9A are reliable.

The TiN EE-ALD deposits on insulating as well as on conducting samples. Electron currents on an insulating substrate might be expected to charge the substrate negatively. This negative charge would then repel additional electron current. Without wishing to be bound by theory, it is believed that if the secondary electron yield is greater than unity, then the sample would charge positive. This positive charge could then pull back secondary electrons to maintain charge neutrality. Secondary electron yields greater than unity have been measured for SiO₂ and Si₃N₄ for primary electron energies from −100-1000 eV. A wide range of insulating materials, such as Al₂O₃, also have secondary electron yields greater than unity. These high secondary electron yields should allow EE-ALD to be performed on insulating substrates.

### Enumerated Embodiments

The following exemplary embodiments are provided, the numbering of which is not to be construed as designating levels of importance:

Embodiment 1 provides a method of promoting nucleation and/or growth of a conductive film on a solid substrate, the method comprising:
(a) contacting at least a portion of a surface of the solid substrate with a volatile metal precursor in the presence of a background gas, wherein the volatile metal precursor is chemisorbed or physisorbed to at least a portion of the surface of the solid substrate to provide a metal precursor-adsorbed substrate surface; and
(b) contacting at least a portion of the metal precursor-adsorbed substrate surface with an electron beam in the presence of the background gas.

Embodiment 2 provides the method of Embodiment 1, wherein the volatile metal precursor comprises at least one selected from the group consisting of a metal, a metal-halogen complex, and a metal-organic complex, and mixtures thereof.

Embodiment 3 provides the method of Embodiment 2, wherein the metal, metal-halogen complex, metal-organic complex, or any mixture thereof, comprises a metal selected from the group consisting of Ti, Ta, W, Mo, Zr, Hf, Zn, Sc, Nb, Cu, Ni, Pt, Ru, Ni, and Al.

Embodiment 4 provides the method of any one of Embodiments 1-3, wherein at least one of the following applies:
(a) the volatile metal precursor is an amide or imide of Be, Sc, Ti, V, Cr, Mn, Fe, Co, Ni, Cu, Zn, Al, Si, Ga, Ge, As, Se, Y, Zr, Nb, Mo, Sn, Sb, Te, La, Hf, Ta, W, Pb, or Bi, optionally wherein the volatile metal precursor is tetrakis(dimethylamino)titanium (TDMAT);
(b) the volatile metal precursor is a halide of B, C, Al, Si, P, Ti, V, Cr, Mn, Cu, Zn, Ga, Ge, Zr, Hb, Mo, Cd, In, Sn, Sb, Hf, Ta, W, or Pb;
(c) the volatile metal precursor is an alkyl of B, Al, Si, Zn, Ga, Ge, Cd, In, Sn, Sb, Te, Hg, or Bi;
(d) the volatile metal precursor is an alkoxide of B, Al, Si, Ti, V, Ni, Ge, Zr, Nb, Hf, Ta, or Gd;
(e) the volatile metal precursor is a cyclopentadienyl of Mg, Ca, Sc, Ti, Mn, Ge, Co, Ni, Sr, Y, Zr, Ru, In, Ba, La, Hf, or Pt; and
(f) the volatile metal precursor comprises a beta-diketonate or amidinate.

Embodiment 5 provides the method of any one of Embodiments 1-4, wherein the background gas has a pressure of about 1 mTorr to about 2 mTorr.

Embodiment 6 provides the method of any one of Embodiments 1-5, wherein the background gas comprises at least one selected from the group consisting of a hydride gas, an oxide gas, a nitride gas, a sulfide gas, and a halide or halogen gas.

Embodiment 7 provides the method of Embodiment 6, wherein at least one of the following applies:
(a) the hydride gas is at least one selected from the group consisting of ammonia (NH₃), CH₄, H₂O, HF, HCl, SiH₄, PH₃, H₂S, GeH₄, AsH₃, and H₂Se;
(b) the oxide gas is at least one selected from the group consisting of O₂, O₃, H₂O₂, and H₂O;
(c) the nitride gas is at least one selected from the group consisting of N₂ and NH₃;
(d) the sulfide gas is at least one selected from the group consisting of S₈ and H₂S; and
(e) the halide or halogen gas is at least one selected from the group consisting of F₂, HF, SF₆, NF₃, BF₃, Cl₂, HCl, BCl₃, HBr, Br₂, BBr₃, HI, and I₂.

Embodiment 8 provides the method of any one of Embodiments 1-7, wherein the solid substrate comprises at least one selected from the group consisting of a semiconductor, ceramic, metal, polymer, and metal-oxide, and mixtures thereof.

Embodiment 9 provides the method of Embodiment 8, wherein the semiconductor comprises silicon.

Embodiment 10 provides the method of Embodiment 8 or 9, wherein the semiconductor is selected from the group consisting of silicon nitride (Si₃N₄), silicon dioxide (SiO₂), and crystalline silicon.

Embodiment 11 provides the method of any one of Embodiments 1-10, wherein the contacting of the volatile metal precursor and the solid substrate occurs for a period of about 0.1 to about 4 seconds.

Embodiment 12 provides the method of any one of Embodiments 1-11, wherein the contacting of the metal precursor-adsorbed substrate surface and the electron beam occurs for a period of about 20 seconds.

Embodiment 13 provides the method of any one of Embodiments 1-12, wherein the electron beam has a current of about 0.1 mA to about 100 mA.

Embodiment 14 provides the method of any one of Embodiments 1-13, wherein the electron beam has an energy of about 1 eV to about 500 eV.

Embodiment 15 provides the method of any one of Embodiments 1-14, wherein the electron beam is generated using a hollow cathode plasma electron source (HC-PES).

Embodiment 16 provides the method of any one of Embodiments 1-15, wherein steps (a) and (b) occur at a temperature of less than 150° C.

Embodiment 17 provides the method of Embodiment 16, wherein steps (a) and (b) occur at a temperature of about 70° C.

Embodiment 18 provides the method of any one of Embodiments 1-19, wherein nucleation occurs by performing about 7 cycles of steps (a)-(b).

Embodiment 19 provides the method of any one of Embodiments 1-18, wherein steps (a)-(b) are repeated one or more times, wherein each cycle of steps (a)-(b) increases conductive film thickness by about 0.5 Å to about 2.0 Å.

Embodiment 20 provides the method of any one of Embodiments 1-19, wherein the conductive film comprises titanium nitride (TiN).

Embodiment 21 provides the method of Embodiment 20, wherein the TiN film comprises at least 91% Ti and N.

Embodiment 22 provides the method of Embodiment 20 or 21, wherein the TiN film has a Ti:N ratio of about 3:4.

Embodiment 23 provides the method of any one of Embodiments 1-22, wherein the conductive film is prepared by performing about 150 cycles of steps (a)-(b).

Embodiment 24 provides the method of any one of Embodiments 1-23, wherein the conductive film has a thickness of about 60 Å to about 70 Å.

Embodiment 25 provides the method of any one of Embodiments 1-24, wherein the conductive film has a resistivity of about 110 μΩ·cm to about 160 μΩ·cm.

Embodiment 26 provides the method of any one of Embodiments 1-22, wherein the conductive film is prepared by performing about 200 cycles of steps (a)-(b).

Embodiment 27 provides the method of any one of Embodiments 1-22 and 26, wherein the conductive film has a thickness of about 125 Å to 135 Å.

Embodiment 28 provides the method of any one of Embodiments 1-22 and 27, wherein the conductive film has a resistivity of about 120 μΩ·cm to about 150 μΩ·cm.

Embodiment 29 provides a microdevice or nanodevice comprising a conductive film prepared according to the method of any one of Embodiments 1-28.

Embodiment 30 provides the microdevice or nanodevice of Embodiment 29, which is selected from the group consisting of a diffusion barrier, liner, transistor, channel materials, via, conduit, and any other electrical circuit components, Josephson junction, superconducting device, electrical conductor, photovoltaic, transistor, diode, waveguide, electrical transmission line, light emitting diode, thermocouple, mirror, absorber for photons, photon emitter, radiation shield, and radiation detector.

Embodiment 31 provides the microdevice or nanodevice of Embodiment 29 or 30, which is selected from the group consisting of a bolometer, transducer, temperature sensor, heater, thermistor, microbolometer, microphone, speaker, ultrasonic transducer, resistor, inductor, spiral inductor, mechanical actuator, flagellum, flagellum motor, freestanding nanodevice, freestanding microdevice, Bragg reflector, Bragg filter, antenna, terahertz detector, electromagnetic transformer, and electrical system.

Embodiment 32 provides the microdevice or nanodevice of any one of Embodiments 29-31, which is selected from the group consisting of a nanotube, nanowire, coaxial wire, hollow tube with nanoscale diameters, periodic structure, or metamaterial.

The terms and expressions employed herein are used as terms of description and not of limitation, and there is no intention in the use of such terms and expressions of excluding any equivalents of the features shown and described or portions thereof, but it is recognized that various modifications are possible within the scope of the embodiments of the present application. Thus, it should be understood that although the present application describes specific embodiments and optional features, modification and variation of the compositions, methods, and concepts herein disclosed may be resorted to by those of ordinary skill in the art, and that such modifications and variations are considered to be within the scope of embodiments of the present application.

What is claimed is:

1. A method of promoting nucleation and/or growth of a conductive film on a solid substrate, the method comprising:
(a) contacting at least a portion of a surface of the solid substrate with a volatile metal precursor in the presence of a background gas, wherein the volatile metal precursor is chemisorbed or physisorbed to at least a portion of the surface of the solid substrate to provide a metal precursor-adsorbed substrate surface; and
(b) contacting at least a portion of the metal precursor-adsorbed substrate surface with an electron beam in the presence of the background gas.

2. The method of claim 1, wherein the volatile metal precursor comprises at least one selected from the group consisting of a metal, a metal-halogen complex, and a metal-organic complex, and mixtures thereof.

3. The method of claim 2, wherein the metal, metal-halogen complex, metal-organic complex, or any mixture thereof, comprises a metal selected from the group consisting of Ti, Ta, W, Mo, Zr, Hf, Zn, Sc, Nb, Cu, Ni, Pt, Ru, Ni, and Al.

4. The method of claim 1, wherein at least one of the following applies:
(a) the volatile metal precursor is an amide or imide of Be, Sc, Ti, V, Cr, Mn, Fe, Co, Ni, Cu, Zn, Al, Si, Ga, Ge, As, Se, Y, Zr, Nb, Mo, Sn, Sb, Te, La, Hf, Ta, W, Pb, or Bi, optionally wherein the volatile metal precursor is tetrakis(dimethylamino)titanium (TDMAT);
(b) the volatile metal precursor is a halide of B, C, Al, Si, P, Ti, V, Cr, Mn, Cu, Zn, Ga, Ge, Zr, Hb, Mo, Cd, In, Sn, Sb, Hf, Ta, W, or Pb;
(c) the volatile metal precursor is an alkyl of B, Al, Si, Zn, Ga, Ge, Cd, In, Sn, Sb, Te, Hg, or Bi;
(d) the volatile metal precursor is an alkoxide of B, Al, Si, Ti, V, Ni, Ge, Zr, Nb, Hf, Ta, or Gd;
(e) the volatile metal precursor is a cyclopentadienyl of Mg, Ca, Sc, Ti, Mn, Ge, Co, Ni, Sr, Y, Zr, Ru, In, Ba, La, Hf, or Pt; and
(f) the volatile metal precursor comprises a beta-diketonate or amidinate.

5. The method of claim 1, wherein the background gas has a pressure of about 1 mTorr to about 2 mTorr.

6. The method of claim 1, wherein the background gas comprises at least one selected from the group consisting of a hydride gas, an oxide gas, a nitride gas, a sulfide gas, and a halide or halogen gas.

7. The method of claim 6, wherein at least one of the following applies:
(a) the hydride gas is at least one selected from the group consisting of ammonia (NH₃), CH₄, H₂O, HF, HCl, SiH₄, PH₃, H₂S, GeH₄, AsH₃, and H₂Se;
(b) the oxide gas is at least one selected from the group consisting of O₂, O₃, H₂O₂, and H₂O;
(c) the nitride gas is at least one selected from the group consisting of N₂ and NH₃;
(d) the sulfide gas is at least one selected from the group consisting of S₈ and H₂S; and
(e) the halide or halogen gas is at least one selected from the group consisting of F₂, HF, SF₆, NF₃, BF₃, Cl₂, HCl, BCl₃, HBr, Br₂, BBr₃, HI, and I₂.

8. The method of claim 1, wherein the solid substrate comprises at least one selected from the group consisting of a semiconductor, ceramic, metal, polymer, and metal-oxide, and mixtures thereof.

9. The method of claim 8, wherein the semiconductor comprises silicon.

10. The method of claim 8, wherein the semiconductor is selected from the group consisting of silicon nitride (Si₃N₄), silicon dioxide (SiO₂), and crystalline silicon.

11. The method of claim 1, wherein the contacting of the volatile metal precursor and the solid substrate occurs for a period of about 0.1 to about 4 seconds.

12. The method of claim 1, wherein the contacting of the metal precursor-adsorbed substrate surface and the electron beam occurs for a period of about 20 seconds.

13. The method of claim 1, wherein the electron beam has a current of about 0.1 mA to about 100 mA.

14. The method of claim 1, wherein the electron beam has an energy of about 1 eV to about 500 eV.

15. The method of claim 1, wherein the electron beam is generated using a hollow cathode plasma electron source (HC-PES).

16. The method of claim 1, wherein steps (a) and (b) occur at a temperature of less than 150° C.

17. The method of claim 16, wherein steps (a) and (b) occur at a temperature of about 70° C.

18. The method of claim 1, wherein nucleation occurs by performing about 7 cycles of steps (a)-(b).

19. The method of claim 1, wherein steps (a)-(b) are repeated one or more times, wherein each cycle of steps (a)-(b) increases conductive film thickness by about 0.5 Å to about 2.0 Å.

20. The method of claim 1, wherein the conductive film comprises titanium nitride (TiN).

21. The method of claim 20, wherein the TiN film comprises at least 91% Ti and N.

22. The method of claim 20, wherein the TiN film has a Ti:N ratio of about 3:4.

23. The method of claim 20, wherein the conductive film is prepared by performing about 150 cycles of steps (a)-(b).

24. The method of claim 23, wherein the conductive film has a thickness of about 60 Å to about 70 Å.

25. The method of claim 23, wherein the conductive film has a resistivity of about 110 μΩ·cm to about 160 μΩ·cm.

26. The method of claim 20, wherein the conductive film is prepared by performing about 200 cycles of steps (a)-(b).

27. The method of claim 26, wherein the conductive film has a thickness of about 125 Å to 135 Å.

28. The method of claim 26, wherein the conductive film has a resistivity of about 120 μΩ·cm to about 150 μΩ·cm.

29. A microdevice or nanodevice comprising a conductive film prepared according to the method of claim 1.

30. The microdevice or nanodevice of claim 29, which is selected from the group consisting of a diffusion barrier, liner, transistor, channel materials, via, conduit, Josephson junction, superconducting device, electrical conductor, photovoltaic, transistor, diode, waveguide, electrical transmission line, light emitting diode, thermocouple, mirror, absorber for photons, photon emitter, radiation shield, and radiation detector.

31. The microdevice or nanodevice of claim 29, which is selected from the group consisting of a bolometer, transducer, temperature sensor, heater, thermistor, microbolometer, microphone, speaker, ultrasonic transducer, resistor, inductor, spiral inductor, mechanical actuator, flagellum, flagellum motor, freestanding nanodevice, freestanding microdevice, Bragg reflector, Bragg filter, antenna, terahertz detector, electromagnetic transformer, and electrical system.

32. The microdevice or nanodevice of claim 29, which is selected from the group consisting of a nanotube, nanowire, coaxial wire, hollow tube with nanoscale diameters, periodic structure, or metamaterial.
